(19) United States
(12) Patent Application Publication
(10) Pub. No.: US 2016/0204056 A1
(43) Pub. Date: Jul. 14, 2016

(54) WIRING BOARD WITH INTERPOSER AND DUAL WIRING STRUCTURES INTEGRATED TOGETHER AND METHOD OF MAKING THE SAME

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 14/994,047

(22) Filed: Jan. 12, 2016

Related U.S. Application Data
(60) Provisional application No. 62/103,529, filed on Jan. 14, 2015.
(60) Provisional application No. 62/103,531, filed on Jan. 14, 2015.

(51) Int. Cl. H01L 23/498; H01L 21/683; H01L 21/48

(52) U.S. Cl. CPC H01L 23/49833; H01L 21/4853; H01L 21/6835; H01L 23/49838; H01L 23/49827; H01L 2221/68381; H01L 2221/68359

(57) ABSTRACT

A wiring board with integrated interposer and dual wiring structures is characterized in that an interposer and a first wiring structure are positioned within a through opening of a stiffener whereas a second wiring structure is disposed beyond the through opening of the stiffener. The mechanical robustness of the stiffener can prevent the wiring board from warping. The interposer provides primary fan-out routing for a semiconductor device to be assembled thereon. The first wiring structure can further enlarge the pad size and pitch of the interposer, whereas the second wiring structure not only provides further fan-out wiring structure, but also mechanically binds the first wiring structure with the stiffener.

### CROSS REFERENCE TO RELATED APPLICATIONS

This application claims the benefit of filing date of U.S. Provisional Application Ser. No. 62/103,529 filed Jan. 14, 2015 and the benefit of the filing date of U.S. Provisional Application Ser. No. 62/103,531 filed Jan. 14, 2015. The entirety of each of said Provisional applications is incorporated herein by reference.

### FIELD OF THE INVENTION

The present invention relates to a wiring board, more particularly, to a wiring board having interposer interconnected to integrated dual wiring structures within and beyond a through opening of a stiffener, respectively, and a method of making the same.

### DESCRIPTION OF RELATED ART

For high pin-count semiconductor chip packaging and assembly, high-density wiring board is needed for mounting a semiconductor chip thereon so that chip I/O pads can be routed to a much large pitch for reliable board-level assembly. For example, U.S. Pat. Nos. 9,060,455, 9,089,041, 8,859,912 and 8,797,757 disclose various coreless substrates for chip fan-out routing purposes. Coreless substrate has several advantages over core-substrate including lower parasitic resistance, lower inductance and capacitance. Most importantly, the interconnect density of coreless substrate is much higher than that of the conventional core substrate, which is a key feature for fine pitch and high I/O applications. However, as coreless substrate tends to warp during the repeated heating and cooling in the process of manufacturing, it is not commonly adopted yet. U.S. Pat. Nos. 8,860,205, 7,981,728 and 7,902,660 intend to solve this issue but with little success.

Worse, as semiconductor chips have a low coefficient of thermal expansion (Si ˜3 to 4 ppm) compared to that of the organic substrate (epoxy resin ˜15 ppm), interfacial stress due to mismatched-CTE often causes poor chip-level connection reliability.

For the reasons stated above, and for other reasons stated below, an urgent need exists to provide a new wiring board that can address high performance IC packaging's needs with better signal integrity, higher production yield, higher reliability and lower cost.

### SUMMARY OF THE INVENTION

A primary objective of the present invention is to provide a wiring board in which an inorganic interposer is integrated on the top surface of the wiring board so that the low-CTE and high-modulus interposer can ensure a reliable interface for chip connection.

Another objective of the present invention is to provide a wiring board in which the interposer is integrated with two wiring structures so that staged fan-out routing can be provided, thereby improving production yield and lowering the cost.

Yet another objective of the present invention is to provide a wiring board in which the interposer and the first wiring structure are positioned within a through opening of a stiffener so that the central area warping and bending of the wiring board can be suppressed, thereby improving chip-level assembly reliability.

Yet another objective of the present invention is to provide a wiring board wherein the second wiring structure is disposed beyond the through opening of the stiffener so that the outmost area warping and bending of the wiring board can be well controlled, thereby improving board-level assembly reliability.

In accordance with the foregoing and other objectives, the present invention provides a wiring board that includes a stiffener, an interposer, a first wiring structure and a second wiring structure. In a preferred embodiment, the stiffener, having a through opening, provides a high modulus anti-warping platform for the interposer and the integrated dual wiring structures; the interposer, positioned within the through opening of the stiffener, provides primary fan-out routing for a chip to be assembled thereon so that the possible bond pad disconnection induced by tight I/O pad pitch can be avoided; the first wiring structure, positioned within the through opening of the stiffener and electrically coupled to the interposer, provides secondary fan-out routing so that the pad size and pitch of the interposer can be further enlarged before proceeding the subsequent formation of the second wiring structure; and the second wiring structure, laterally extending on the stiffener and electrically connected to the first wiring structure, mechanically binds the first wiring structure with the stiffener and provides further fan-out routing and has pad pith and size that match the next level assembly.

In another aspect, the present invention provides a wiring board with integrated interposer and dual wiring structures, comprising: an interposer having contact pads at a first surface thereof, bond pads at an opposite second surface thereof, and metallized vias electrically coupled to the bond pads and the contact pads; a first wiring structure that covers the first surface and sidewalls of the interposer and is electrically coupled to the contact pads of the interposer and includes at least one conductive trace laterally extending beyond peripheral edges of the interposer; a second wiring structure that is electrically coupled to the first wiring structure and includes at least one conductive trace laterally extending over and beyond peripheral edges of the first wiring structure; and a stiffener having a through opening that extends through the stiffener, wherein the interposer and the first wiring structure are positioned within the through opening of the stiffener and the second wiring structure is disposed beyond the through opening of the stiffener and on an exterior surface of the stiffener.

In yet another aspect, the present invention provides a method of making a wiring board with integrated interposer and dual wiring structures, comprising steps of: providing an electronic component that includes a detachable sacrificial carrier, an interposer and a first wiring structure, wherein (i) the interposer has contact pads at a first surface thereof, bond pads at an opposite second surface thereof and metallized vias electrically coupled to the contact pads and the bond pads, and is disposed over the sacrificial carrier with the second surface facing the sacrificial carrier; and (ii) the first wiring structure covers the sacrificial carrier and the first surface and sidewalls of the interposer and is electrically coupled to the contact pads of the interposer and includes at least one conductive trace laterally extending beyond peripheral edges of the interposer; providing a stiffener that has a through opening extending through the stiffener; inserting the electronic component into the through opening of the stiffener; forming a second wiring structure that is electrically coupled to the first wiring structure and disposed beyond the through opening of the stiffener and on an exterior surface of the stiffener and includes at least one conductive trace laterally extending over and beyond peripheral edges of the first wiring structure; and removing the sacrificial carrier to expose the bond pads of the interposer.

Unless specifically indicated or using the term “then” between steps, or steps necessarily occurring in a certain order, the sequence of the above-mentioned steps is not limited to that set forth above and may be changed or reordered according to desired design.

The method of making a wiring board according to the present invention has numerous advantages. For instance, inserting the electronic component into the through opening of the stiffener before the formation of the second wiring structure is particularly advantageous as the sacrificial carrier of the electronic component together with the stiffener provides a stable platform for forming the second wiring structure and micro-via connection failure in the subsequent formation of the second wiring structure can be avoided. Additionally, the three-stage formation of the interconnect substrate for a chip is beneficial as the interposer can provide primary fan-out routing and a CTE-matched interface whereas the dual buildup circuitries provide further fan-out routing and horizontal interconnections, and serious warping problem can be avoided when multiple layers of wiring circuitries are need.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are cross-sectional and top perspective views, respectively, showing a structure with alignment guides formed on a sacrificial carrier in accordance with the first embodiment of the present invention;

FIGS. 3 and 4 are cross-sectional and top perspective views, respectively, showing interposers are attached to the sacrificial carrier of FIGS. 1 and 2 in accordance with the first embodiment of the present invention;

FIG. 5 is a cross-sectional view showing the structure of FIG. 3 is provided with a balancing layer in accordance with the first embodiment of the present invention;

FIG. 6 is a cross-sectional view showing the structure of FIG. 5 is provided with a first dielectric layer and first via openings in accordance with the first embodiment of the present invention;

FIG. 7 is a cross-sectional view showing the structure of FIG. 6 is provided with first conductive traces in accordance with the first embodiment of the present invention;

FIG. 8 is a cross-sectional view showing the structure of FIG. 7 is provided with a second dielectric layer and second via openings in accordance with the first embodiment of the present invention;

FIG. 9 is a cross-sectional view showing the structure of FIG. 8 is provided with second conductive traces in accordance with the first embodiment of the present invention;

FIGS. 10 and 11 are cross-sectional and top perspective views, respectively, of a diced state of the panel-scale structure of FIG. 9 in accordance with the first embodiment of the present invention;

FIGS. 12 and 13 are cross-sectional and top perspective views, respectively, of an electronic component corresponding to a diced unit in FIGS. 10 and 11 in accordance with the first embodiment of the present invention;

FIG. 14 is a cross-sectional view of a stiffener on a carrier film in accordance with the first embodiment of the present invention;

FIG. 15 is a cross-sectional view showing the electronic component of FIG. 12 is attached to the carrier film of FIG. 14 in accordance with the first embodiment of the present invention;

FIG. 16 is a cross-sectional view showing the structure of FIG. 15 is provided with a third dielectric layer and a metal layer in accordance with the first embodiment of the present invention;

FIG. 17 is a cross-sectional view showing the structure of FIG. 16 is provided with third via openings in accordance with the first embodiment of the present invention;

FIG. 18 is a cross-sectional view showing the structure of FIG. 17 is provided with third conductive traces in accordance with the first embodiment of the present invention;

FIG. 19 is a cross-sectional view showing the carrier film and the sacrificial carrier are removed from the structure of FIG. 18 in accordance with the first embodiment of the present invention;

FIGS. 20 and 21 are cross-sectional and bottom perspective views, respectively, showing the adhesive is removed from the structure of FIG. 19 to finish the fabrication of a wiring board in accordance with the first embodiment of the present invention;

FIG. 22 is a cross-sectional view of a semiconductor assembly with a semiconductor device mounted on the wiring board of FIG. 20 in accordance with the first embodiment of the present invention;

FIGS. 23 and 24 are cross-sectional and bottom perspective views, respectively, of a substrate having blind vias formed therein in accordance with the second embodiment of the present invention;

FIG. 25 is a cross-sectional view showing the structure of FIG. 23 is provided with metallized vias in accordance with the second embodiment of the present invention;

FIGS. 26 and 27 are cross-sectional and bottom perspective views, respectively, showing the structure of FIG. 25 is provided with routing traces to finish the fabrication of a semi-finished interposer panel in accordance with the second embodiment of the present invention;

FIGS. 28 and 29 are cross-sectional and bottom perspective views, respectively, of a diced state of the panel-scale structure of FIGS. 26 and 27 in accordance with the second embodiment of the present invention;

FIGS. 30 and 31 are cross-sectional and bottom perspective views, respectively, of a semi-finished interposer corresponding to a diced unit in FIGS. 28 and 29 in accordance with the second embodiment of the present invention;

FIGS. 32 and 33 are cross-sectional and top perspective views, respectively, showing a structure with alignment guides formed on a sacrificial carrier in accordance with the second embodiment of the present invention;

FIGS. 34 and 35 are cross-sectional and top perspective views, respectively, showing the semi-finished interposers of FIGS. 30 and 31 are attached to the sacrificial carrier of FIGS. 32 and 33 in accordance with the second embodiment of the present invention;

FIG. 36 is a cross-sectional view showing the structure of FIG. 34 is provided with a balancing layer in accordance with the second embodiment of the present invention;

FIG. 37 is a cross-sectional view showing the structure of FIG. 36 is partially removed in accordance with the second embodiment of the present invention;

FIGS. 38 and 39 are cross-sectional and top perspective views, respectively, showing the structure of FIG. 37 is provided with routing traces in accordance with the second embodiment of the present invention;

FIG. 40 is a cross-sectional view showing the structure of FIG. 38 is provided with a first dielectric layer and first via openings in accordance with the second embodiment of the present invention;

FIG. 41 is a cross-sectional view showing the structure of FIG. 40 is provided with first conductive traces in accordance with the second embodiment of the present invention;

FIGS. 42 and 43 are cross-sectional and top perspective views, respectively, of a diced state of the panel-scale structure of FIG. 41 in accordance with the second embodiment of the present invention;

FIGS. 44 and 45 are cross-sectional and top perspective views, respectively, of an electronic component corresponding to a diced unit in FIGS. 42 and 43 in accordance with the second embodiment of the present invention;

FIG. 46 is a cross-sectional view showing the electronic component of FIG. 44 is attached to the carrier film of FIG. 14 in accordance with the second embodiment of the present invention;

FIG. 47 is a cross-sectional view showing the structure of FIG. 46 is provided with a second dielectric layer and a metal layer in accordance with the second embodiment of the present invention;

FIG. 48 is a cross-sectional view showing the structure of FIG. 47 is provided with second via openings in accordance with the second embodiment of the present invention;

FIG. 49 is a cross-sectional view showing the structure of FIG. 48 is provided with second conductive traces in accordance with the second embodiment of the present invention;

FIG. 50 is a cross-sectional view showing the carrier film and the sacrificial carrier are removed from the structure of FIG. 49 in accordance with the second embodiment of the present invention;

FIG. 51 is a cross-sectional view showing the adhesive is removed from the structure of FIG. 50 to finish the fabrication of a wiring board in accordance with the second embodiment of the present invention;

FIG. 52 is a cross-sectional view showing a structure with the electronic component of FIG. 44 and a stiffener on a second dielectric layer/a metal layer in accordance with the third embodiment of the present invention;

FIG. 53 is a cross-sectional view showing the structure of FIG. 52 is subjected to a lamination process in accordance with the second embodiment of the present invention;

FIG. 54 is a cross-sectional view showing the structure of FIG. 53 is provided with second via openings in accordance with the third embodiment of the present invention;

FIG. 55 is a cross-sectional view showing the structure of FIG. 54 is provided with second conductive traces in accordance with the third embodiment of the present invention;

FIG. 56 is a cross-sectional view showing the sacrificial carrier and the adhesive are removed from the structure of FIG. 55 to finish the fabrication of a wiring board in accordance with the third embodiment of the present invention; and

FIG. 57 is a cross-sectional view of a semiconductor assembly with a semiconductor device mounted on the wiring board of FIG. 56 in accordance with the third embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

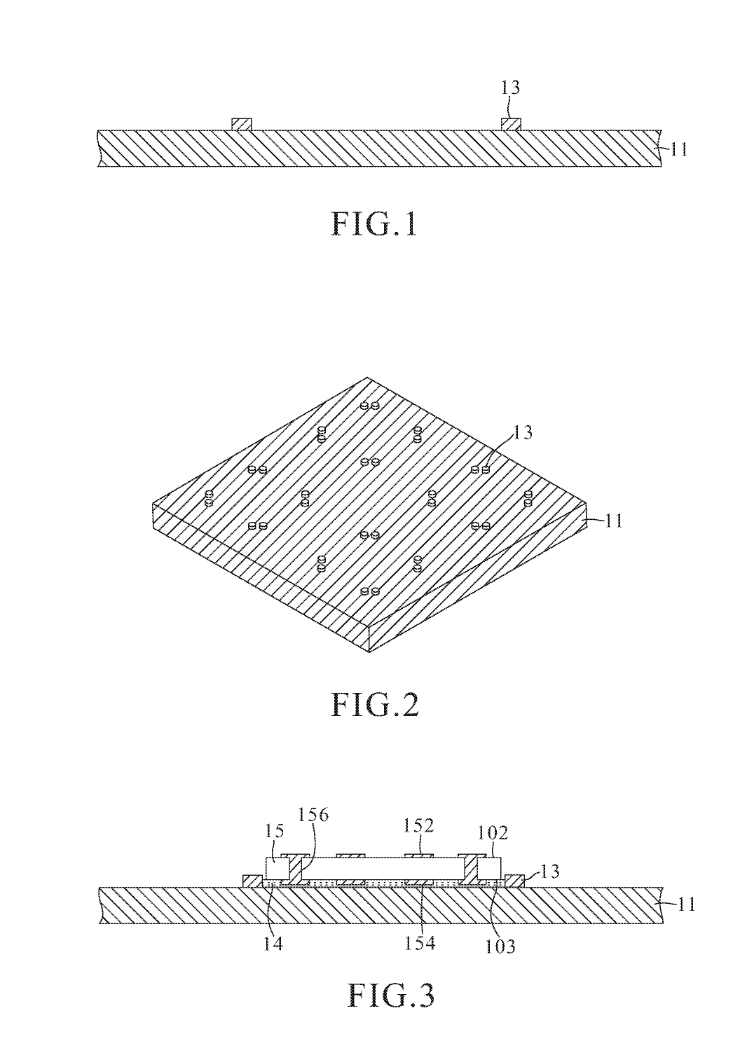

FIGS. 1-21 are schematic views showing a method of making a wiring board that includes an interposer 15, a first wiring structure 17, a stiffener 20 and a second wiring structure 40 in accordance with an embodiment of the present invention.

FIGS. 1 and 2 are cross-sectional and top perspective views, respectively, of the structure with multiple sets of alignment guides 13 on a sacrificial carrier 11. The sacrificial carrier 11 typically is made of copper, aluminum, iron, nickel, tin, stainless steel, or other metals or alloys, but any other conductive or non-conductive material also may be used. The thickness of the sacrificial carrier 11 preferably ranges from 0.1 to 2.0 mm. The alignment guides 13 project from the top surface of the sacrificial carrier 11 and can have a thickness of 5 to 200 microns. In this embodiment, the sacrificial carrier 11 has a thickness of 1.0 mm, whereas the alignment guides 13 have a thickness of 50 microns. For a conductive sacrificial carrier 11, the alignment guides 13 typically are formed on the sacrificial carrier 11 by pattern deposition of metal (such as copper), such as electroplating, electroless plating, evaporating, sputtering or their combinations using photolithographic process. Alternatively, if a non-conductive sacrificial carrier 11 is used, a solder mask or photo resist may be used to form the alignment guides 13. As shown in FIG. 2, each set of the alignment guides 13 consists of plural posts and conform to four corners of a subsequently disposed interposer. However, the alignment guide patterns are not limited thereto and can be in other various patterns against undesirable movement of the subsequently disposed interposer. For instance, the alignment guide 13 may consist of a continuous or discontinuous strip and conform to four sides, two diagonal corners or four corners of a subsequently disposed interposer. Alternatively, the alignment guide 13 may laterally extend to the peripheral edges of the sacrificial carrier 11 and have inner peripheral edges that conform to the peripheral edges of a subsequently disposed interposer.

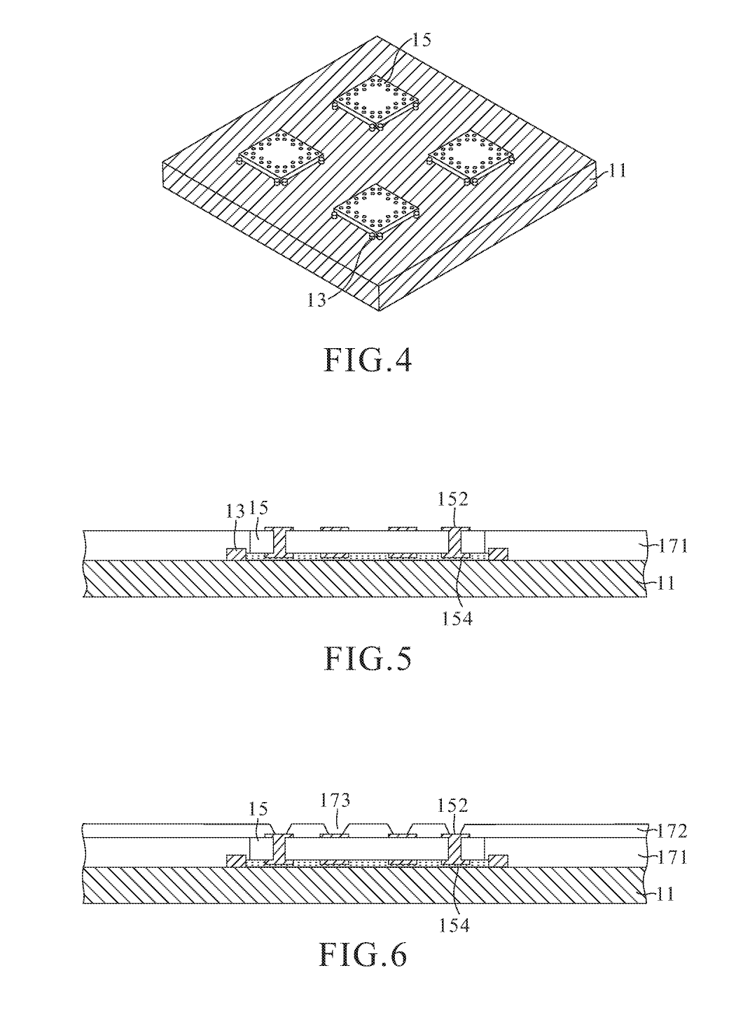

FIGS. 3 and 4 are cross-sectional and top perspective views, respectively, of the structure with interposers 15 attached to the sacrificial carrier 11 using an adhesive 14. Each interposer 15 includes contact pads 152 at its first surface 102, bond pads 154 at its opposite second surface 103, and metallized vias 156 electrically coupled to the contact pads 152 and the bond pads 154. The interposers 15 can be silicon, glass or ceramic interposers, and have a thickness of 50 microns to 500 microns. In this embodiment, the thickness of the interposers 15 is 200 microns. The interposers 15 are attached to the sacrificial carrier 11 with its second surface 103 facing the sacrificial carrier 11 and each set of the alignment guide 13 laterally aligned with and in close proximity to the peripheral edges of each interposer 15. The interposer placement accuracy is provided by the alignment guide 13. The alignment guide 13 extends beyond the second surface 103 of the interposer 15 in the upward direction and is located beyond and laterally aligned with the four corners of the interposer 15 in the lateral directions. As the alignment guide 13 is in close proximity to and conforms to the four corners of the interposer 15 in lateral directions, any undesirable movement of the interposer 15 due to adhesive curing can be avoided. Preferably, a gap in between the alignment guide 13 and the interposer 15 is in a range of about 5 to 50 microns. The interposer 15 can also be attached without the alignment guide 13. For instance, in the aspect of the interposer 15 having large pad size and pitch at its first surface 102, even if no alignment guide 13 is provided to ensure the placement accuracy of the interposer 15, it does not result in micro-via connection failure in the subsequent process of forming buildup circuitry on the interposer 15.

FIG. 5 is a cross-sectional view of the structure with a balancing layer 171 on the sacrificial carrier 11 by, for example, resin lamination, spin coating or molding. The balancing layer 171 covers the sacrificial carrier 11 and the alignment guides 13 from above and surrounds and conformally coats and covers sidewalls of the interposers 15 and extends laterally from the interposers 15 to the peripheral edges of the structure. In this embodiment, the balancing layer 171 has a thickness of about 0.2 mm which is close to the thickness of the interposers 15. Further, the balancing layer 171 can be made of epoxy resin, glass-epoxy, polyimide, and the like.

FIG. 6 is a cross-sectional view of the structure with a first dielectric layer 172 laminated/coated on the interposers 15 and the balancing layer 171 and first via openings 173 in the first dielectric layer 172. The first dielectric layer 172 contacts and covers and extends laterally on the interposers 15 and the balancing layer 171 from above. The first dielectric layer 172 typically has a thickness of 50 microns, and can be made of epoxy resin, glass-epoxy, polyimide, or the like. After the deposition of the first dielectric layer 172, the first via openings 173 are formed by numerous techniques, such as laser drilling, plasma etching and photolithography, and typically have a diameter of 50 microns. Laser drilling can be enhanced by a pulsed laser. Alternatively, a scanning laser beam with a metal mask can be used. The first via openings 173 extend through the first dielectric layer 172 and are aligned with the contact pads 152 of the interposers 15.

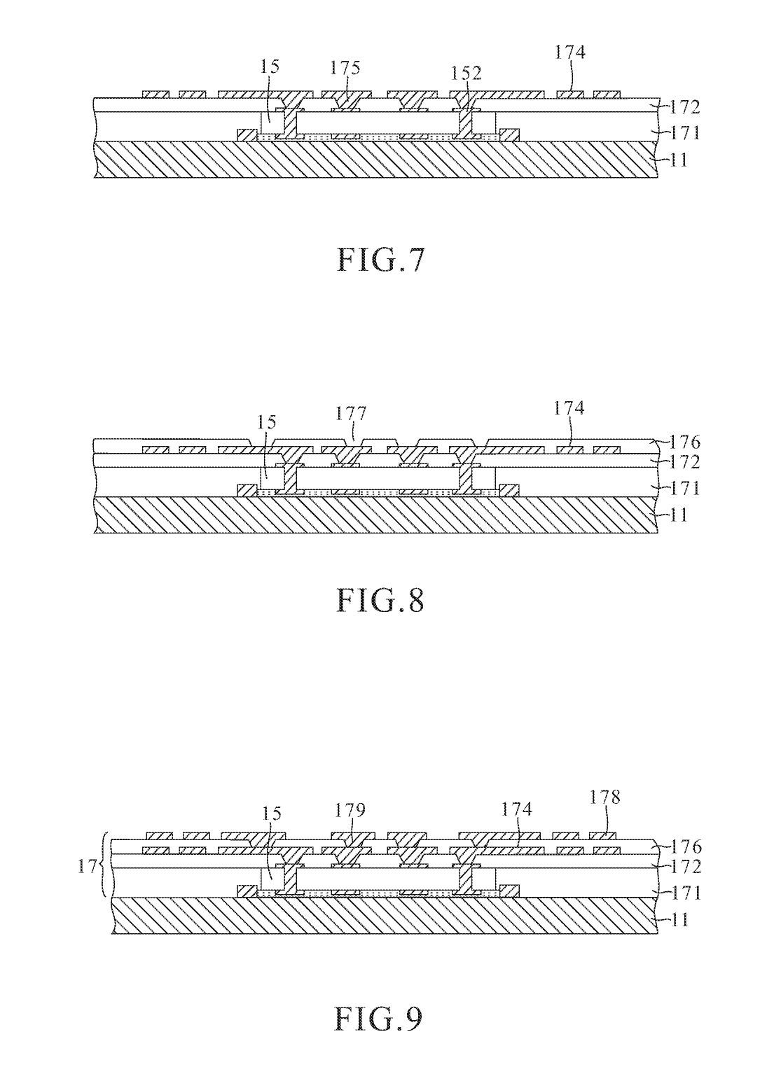

Referring now to FIG. 7, first conductive traces 174 are formed on the first dielectric layer 172 by metal deposition and metal patterning process. The first conductive traces 174 extend from the contact pads 152 of the interposers 15 in the upward direction, fill up the first via openings 173 to form first conductive vias 175 in direct contact with the contact pads 152, and extend laterally on the first dielectric layer 172. As a result, the first conductive traces 174 can provide horizontal signal routing in both the X and Y directions and vertical routing through the first via openings 173 and serve as electrical connections for the contact pads 152 of the interposers 15.

The first conductive traces 174 can be deposited as a single layer or multiple layers by any of numerous techniques, such as electroplating, electroless plating, evaporating, sputtering, or their combinations. For instance, they can be deposited by first dipping the structure in an activator solution to render the first dielectric layer 172 catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, the plated layer can be patterned to form the first conductive traces 174 by any of numerous techniques, such as wet etching, electro-chemical etching, laser-assist etching, or their combinations, with an etch mask (not shown) thereon that defines the first conductive traces 174.

FIG. 8 is a cross-sectional view of the structure with a second dielectric layer 176 laminated/coated on the first dielectric layer 172 as well as the first conductive traces 174 and second via openings 177 in the second dielectric layer 176. The second dielectric layer 176 contacts and covers and extends laterally on the first dielectric layer 172 and the first conductive traces 174 from above. The second dielectric layer 176 typically has a thickness of 50 microns, and can be made of epoxy resin, glass-epoxy, polyimide, or the like. After the deposition of the second dielectric layer 176, the second via openings 177 are formed and extend through the second dielectric layer 176 to expose selected portions of the first conductive traces 174. Like the first via openings 173, the second via openings 177 can be formed by any of numerous techniques, such as laser drilling, plasma etching and photolithography and typically have a diameter of 50 microns.

FIG. 9 is a cross-sectional perspective view of the structure provided with second conductive traces 178 on the second dielectric layer 176 by metal deposition and metal patterning process. The second conductive traces 178 extend from the first conductive traces 174 in the upward direction, fill up the second via openings 177 to form second conductive vias 179 in direct contact with the first conductive traces 174, and extend laterally on the second dielectric layer 176.

At this stage, the formation of a first wiring structure 17 on the interposers 15 is accomplished. In this illustration, the first wiring structure 17 includes a balancing layer 171, a first dielectric layer 172, first conductive traces 174, a second dielectric layer 176 and second conductive traces 178. Accordingly, the contact pad pitch of the interposers 15 can be further enlarged by wiring layers each of which includes a dielectric layer and conductive traces so as to ensure a higher manufacturing yield for the next level buildup circuitry interconnection.

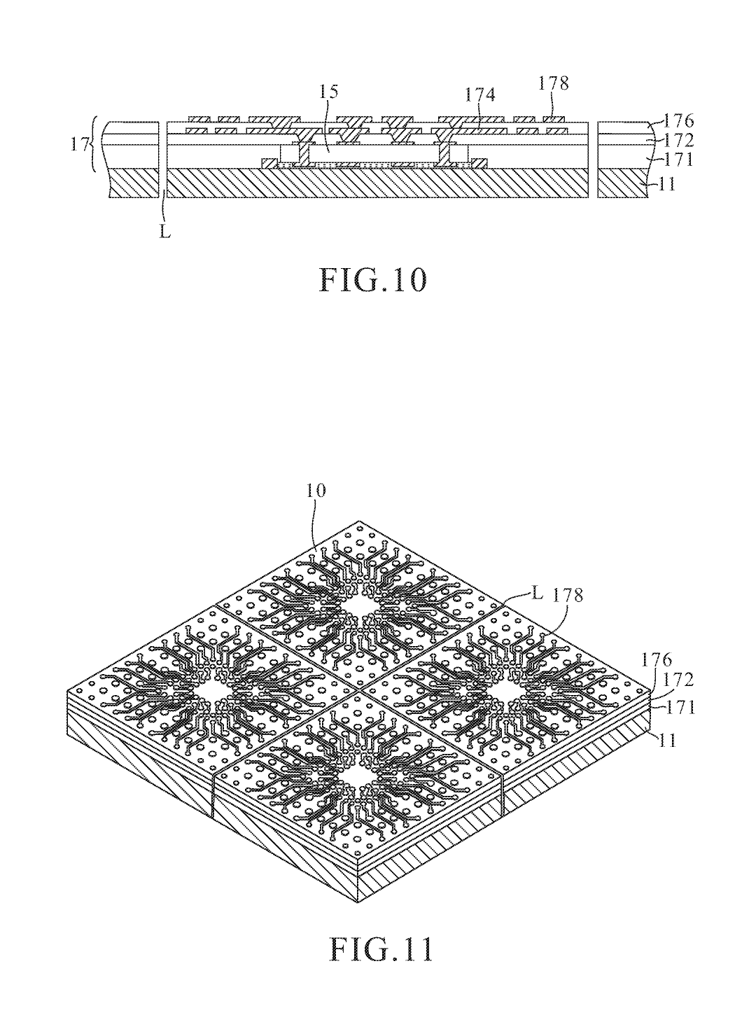

FIGS. 10 and 11 are cross-sectional and top perspective views, respectively, of the panel-scale structure of FIG. 9 diced into individual pieces. The panel-scale structure, having the first wiring structure 17 electrically coupled to the interposers 15, is singulated into individual electronic component 10 along dicing lines “L”.

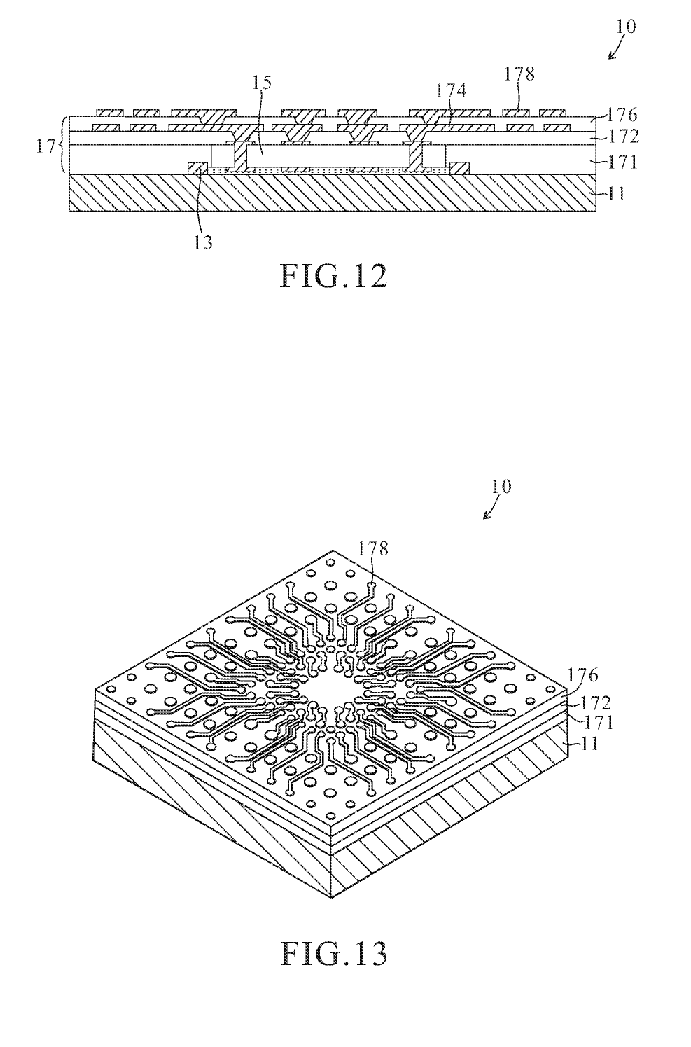

FIGS. 12 and 13 are cross-sectional and top perspective views, respectively, of an individual electronic component 10 that includes a sacrificial carrier 11, an alignment guide 13, an interposer 15 and a first wiring structure 17. In this illustration, the first wiring structure 17 is a buildup circuitry that contacts and laterally extends on the first surface 102 of the interposer 15 and laterally extends beyond peripheral edges of the interposer 15 and surrounds sidewalls of the interposer 15. As such, the surface area of the first wiring structure 17 is larger than that of the interposer 15, and provide first level fan-out routing for the interposer 15.

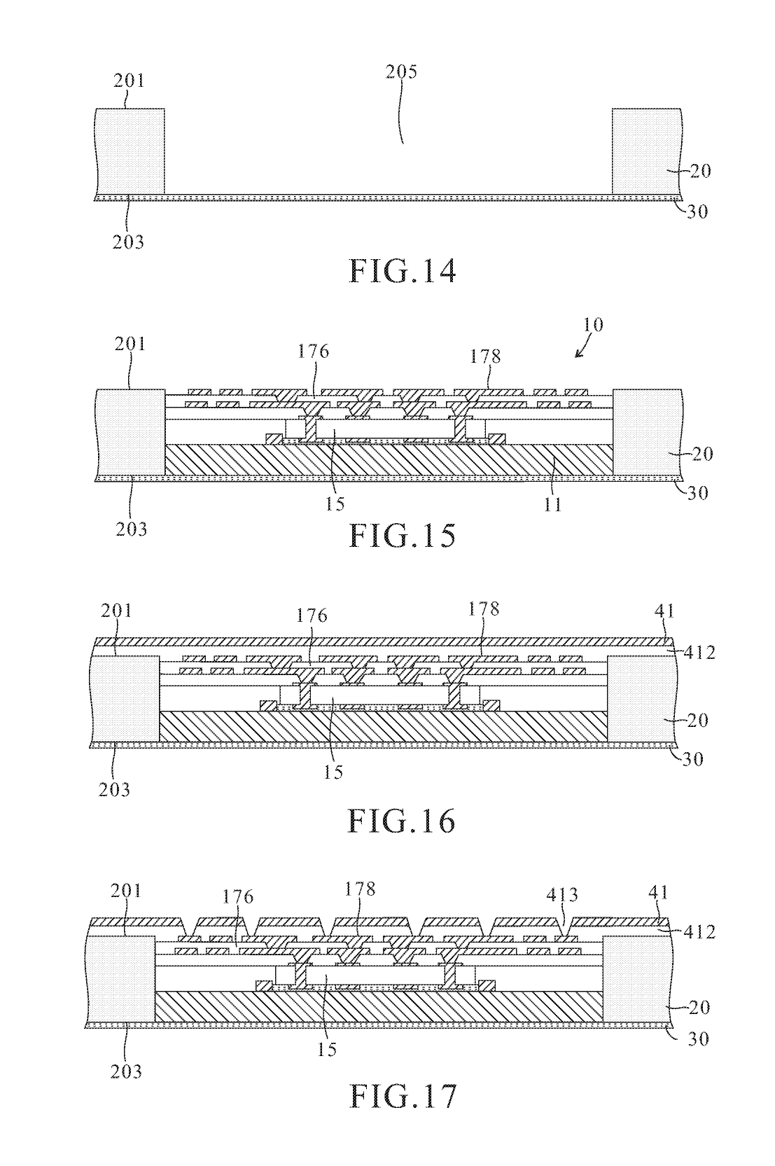

FIG. 14 is a cross-sectional view of a stiffener 20 on a carrier film 30. The stiffener 20 has a first surface 201, an opposite second surface 203, and a through opening 205 that extends through the stiffener 20 between the first surface 201 and the second surface 203. The stiffener 20 can be made of metal, composites of metal, ceramic, resin or other non-metallic materials, and may be a single or multi-layer circuitry structure which has enough mechanical robustness. The stiffener 20 having the through opening 205 can be fabricated by casting, forging, plating, stamping, machining, molding, combinations thereof or other techniques. The stiffener 20 preferably has a thickness substantially the same as that of the electronic component 10, and the through opening 205 has a dimension that is substantially the same or slightly larger than the electronic component 10. The carrier film 30 typically is a tape, and the second surface 203 of the stiffener 20 is attached to the carrier film 30 by the adhesive property of the carrier film 30.

FIG. 15 is a cross-sectional view of the structure with the electronic component 10 inserted in the through opening 205 of the stiffener 20 with the sacrificial carrier 11 attached on the carrier film 30. The carrier film 30 can provide temporary retention force for the electronic component 10 steadily residing within the through opening 205. The peripheral edges of the first wiring structure 17 and the sacrificial carrier 11 are in close proximity to sidewalls of the through opening 205 of the stiffener 20. In this illustration, the electronic component 10 is attached to the carrier film 30 by the adhesive property of the carrier film 30. Alternatively, the electronic component 10 may be attached to the carrier film 30 by dispensing extra adhesive. After the insertion of the electronic component 10 into the through opening 205, the outmost surface of the first wiring structure 17 is substantially coplanar with the first surface 201 of the stiffener 20 in the upward direction. In the case of the through opening 205 having a slightly larger area than the electronic component 10, an adhesive (not shown in the figure) may be optionally dispensed in a gap (not shown in the figure) located in the through opening 205 between the electronic component 10 and the stiffener 20 to provide secure robust mechanical bonds between the first wiring structure 17 and the stiffener 20.

FIG. 16 is a cross-sectional view of the structure with a third dielectric layer 412 and a metal layer 41 laminated/coated on the electronic component 10 and the stiffener 20 from above. The third dielectric layer 412 contacts and is sandwiched between the second dielectric layer 176/the second conductive traces 178 and the metal layer 41 and between the stiffener 20 and the metal layer 41. The third dielectric layer 412 can be formed of epoxy resin, glass-epoxy, polyimide, and the like, and typically has a thickness of 50 microns. The metal layer 41 typically is a copper layer with a thickness of 25 microns.

FIG. 17 is a cross-sectional view of the structure provided with the third via openings 413 to expose selected portions of the second conductive traces 178. The third via openings 413 extend through the metal layer 41 and the third dielectric layer 412, and are aligned with the selected portions of the second conductive traces 178. Like the first and second via openings 173, 177, the third via openings 413 can be formed by any of numerous techniques, such as laser drilling, plasma etching and photolithography and typically have a diameter of 50 microns.

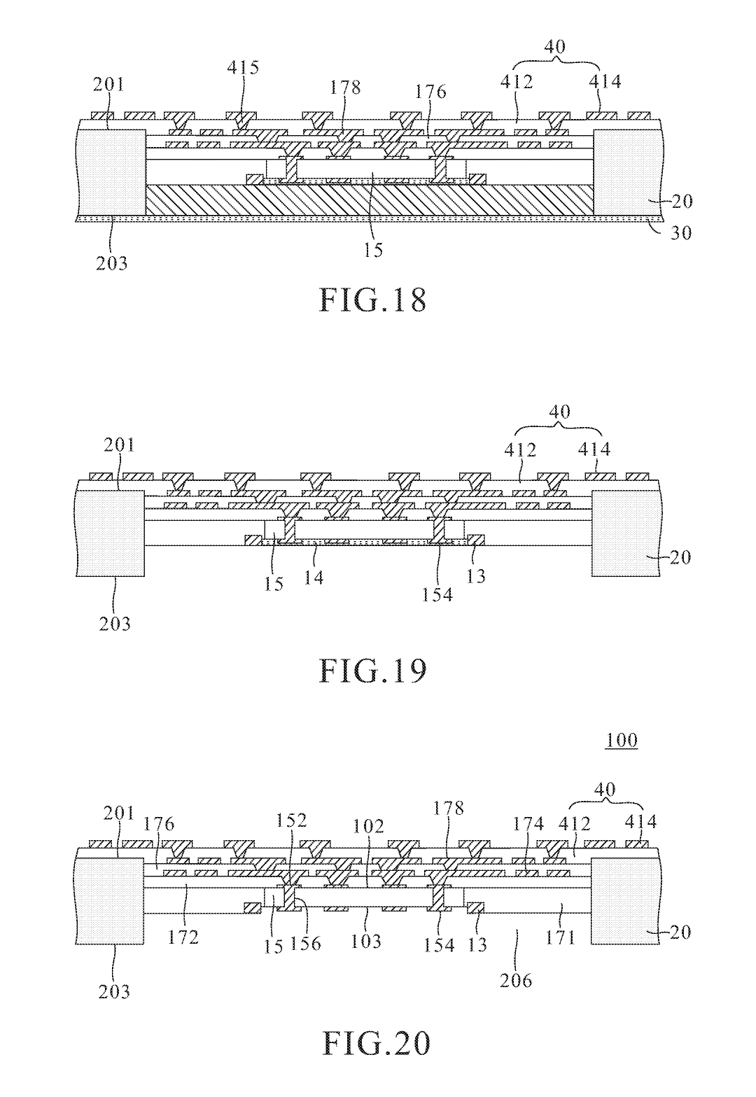

Referring now to FIG. 18, third conductive traces 414 are formed on the third dielectric layer 412 by metal deposition and metal patterning process. The third conductive traces 414 extend from the second conductive traces 178 in the upward direction, fill up the third via openings 413 to form third conductive vias 415 in direct contact with the second conductive traces 178, and extend laterally on the third dielectric layer 412.

At this stage, the formation of a second wiring structure 40 on the second dielectric layer 176/the second conductive traces 178 of the electronic component 10 and the first surface 201 of the stiffener 20 is accomplished. In this illustration, the second wiring structure 40 includes a third dielectric layer 412 and third conductive traces 414. The second wiring structure 40 contacts and laterally extends on the second dielectric layer 176/the second conductive traces 178 of the first wiring structure 17 and the first surface 201 of the stiffener 20, and laterally extends beyond peripheral edges of the first wiring structure 17. As such, the surface area of the second wiring structure 40 is larger than that of the first wiring structure 17. Specifically, the second wiring structure 40 substantially has a combined surface area of the first wiring structure 17 and the stiffener 20.

FIG. 19 is a cross-sectional view of the structure after removal of the carrier film 30 and the sacrificial carrier 11. The carrier film 30 is detached from the sacrificial carrier 11 and the stiffener 20, followed by removing the sacrificial carrier 11. The sacrificial carrier 11 can be removed by numerous techniques, such as wet chemical etching using acidic solution (e.g., ferric chloride, copper sulfate solutions) or alkaline solution (e.g., ammonia solution), electro-chemical etching, or mechanical process such as a drill or end mill followed by chemical etching. Further, in some cases, the alignment guide 13 may be removed together with the sacrificial carrier 11.

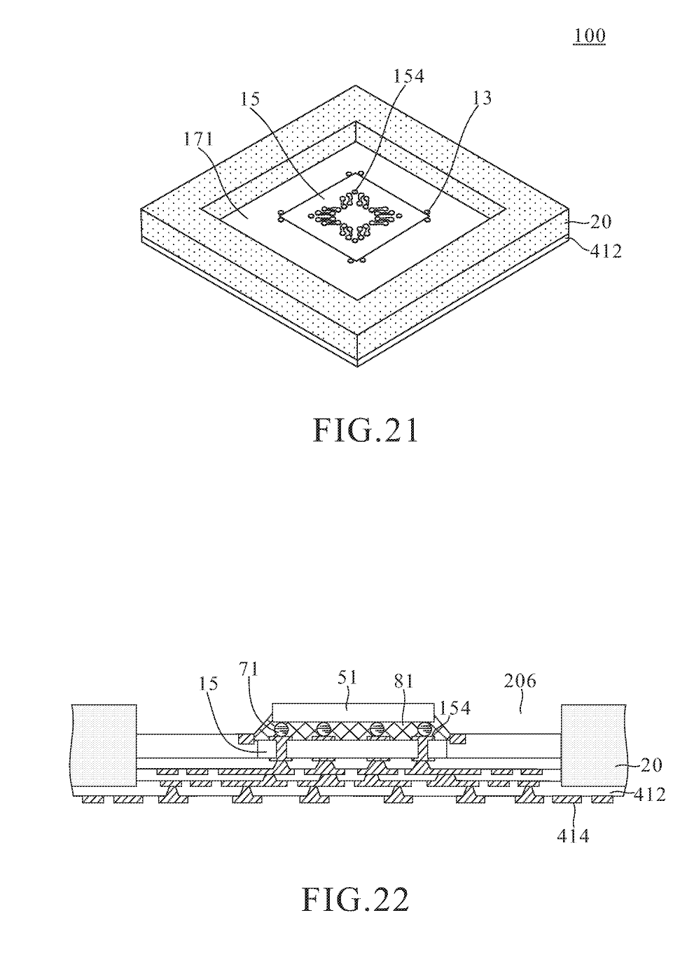

FIGS. 20 and 21 are cross-sectional and bottom perspective views, respectively, of the structure after removal of the adhesive 14. The adhesive 14 is removed from the second surface 103 of the interposer 15 typically by etching techniques, such as reactive ion etching plasma etching, laser ablation or combination thereof. As a result, the bond pads 154 at the second surface 103 of the interposer 15 are exposed from below.

Accordingly, as shown in FIGS. 20 and 21, a wiring board 100 is accomplished and includes an alignment guide 13, an interposer 15, a first wiring structure 17, a stiffener 20 and a second wiring structure 40, and both first and second wiring structures 17, 40 are sequentially formed buildup circuitries.

The interposer 15 is positioned within the through opening 205 of the stiffener 20, with the alignment guide 13 around its second surface 103 and conforming to its four corners. The interposer 15 contains a pattern of traces that fan out from a finer pitch at the bond pads 154 to a coarser pitch at the contact pads 152. As a result, the interposer 15 can provide a primary fan-out routing for a chip to be assembled on the bond pads 154. Further, the interposer 15 has a smaller thermal expansion coefficient and higher modulus than that of the first wiring structure 17 and the second siring structure 40 so as to ensure a reliable interface for chip connection.

The first wiring structure 17 is positioned within the through opening 205 of the stiffener 20 and electrically coupled to the contact pads 152 of the interposer 15 through the first conductive vias 175 of the first wiring structure 17. The first wiring structure 17 includes first conductive traces 174 and second conductive traces 178 laterally extending beyond peripheral edges of the interposer 15 and provides first level fan-out routing for the interposer 15.

The second wiring structure 40 is disposed beyond the through opening 205 of the stiffener 20 and electrically coupled to the second conductive traces 178 of the first wiring structure 17 through the third conductive vias 415 of the second wiring structure 40. The second wiring structure 40 includes third conductive traces 414 extending into an area outside of the through opening 205 of the stiffener 20 and laterally extending beyond peripheral edges of the first wiring structure 17 and over the first surface 201 of the stiffener 20. As such, the second wiring structure 40 not only provides further fan-out wiring structure for the interposer 15, but also mechanically binds the first wiring structure 17 with the stiffener 20.

The stiffener 20 surrounds peripheral edges of the first wiring structure 17 and laterally extends to the peripheral edges of the wiring board 100 to provide mechanical support and suppress warping and bending of the wiring board 100. The stiffener 20 also extends beyond the second surface 103 of the interposer 15 in the downward direction to form a cavity 206 in the through opening 205 of the stiffener 20, and the first surface 201 of the stiffener 20 is substantially coplanar with the surface of the second conductive traces 178 of the first wiring structure 17 in the upward direction.

FIG. 22 is a cross-sectional view of a semiconductor assembly with a semiconductor device 51, illustrated as a chip, mounted on the wiring board 100 illustrated in FIG. 20. The semiconductor device 51 is positioned within the cavity 206 and is flip-chip mounted on the exposed bond pads 154 of the interposer 15 via solder bumps 71. Optionally, underfill 81 can be further provided to fill the gap between the semiconductor device 51 and the interposer 15.

### Embodiment 2

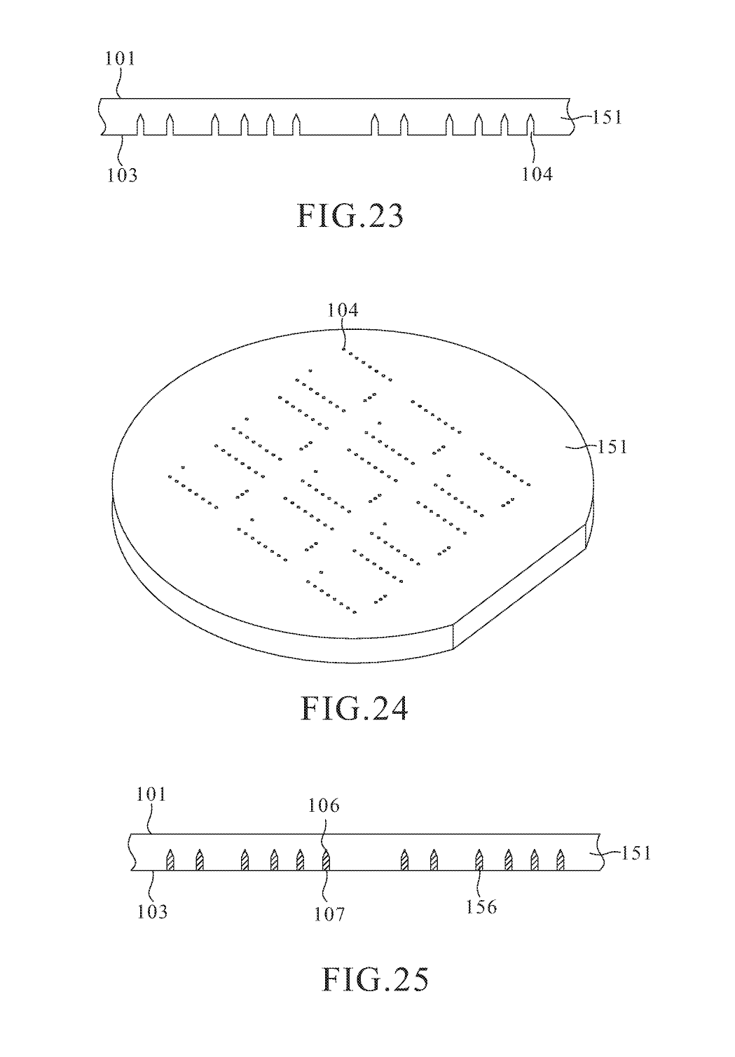

FIGS. 23-51 are schematic views showing another method of making a wiring board that includes a step of attaching semi-finished interposers to sacrificial carrier in accordance with another embodiment of the present invention.

For purposes of brevity, any description in Embodiment 1 above is incorporated herein insofar as the same is applicable, and the same description need not be repeated.

FIGS. 23 and 24 are cross-sectional and bottom perspective views, respectively, of a substrate 151 having a first surface 101, an opposite second surface 103, and blind vias 104 formed in the second surface 103. The substrate 151 can be made of silicon, glass or ceramic and have a thickness of 50 microns to 500 microns. The blind vias 104 can have a depth of 25 microns to 250 microns. In this embodiment, the substrate 151 is a silicon wafer and has a thickness of 200 microns, and the blind vias 104 are formed with a depth of 150 microns.

FIG. 25 is a cross-sectional view of the structure provided with metallized vias 156. The metallized vias 156 are formed in the substrate 151 by metal deposition in the blind vias 104. Each metallized via 156 has a first end 106 spaced from the first surface 101 of the substrate 151 and an opposite second end 107 substantially coplanar with the second surface 103 of the substrate 151. For the aspect of using a silicon substrate, an insulative/passivation layer such as a silicon oxide layer (not shown in the figures) is needed on the sidewalls of the blind vias 104 before metal deposition as silicon is a semiconductor material.

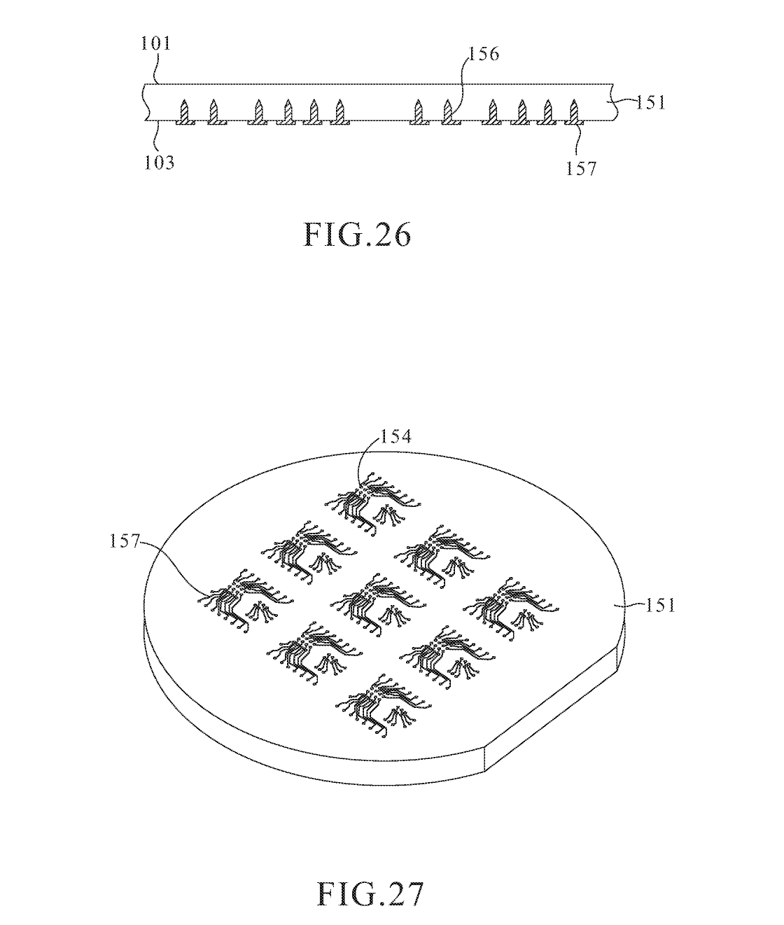

FIGS. 26 and 27 are cross-sectional and bottom perspective views, respectively, of the structure having bottom routing traces 157 at the second surface 103 of the substrate 151. The second surface 103 of the substrate 151 can be metallized by numerous techniques, such as electroplating, electroless plating, evaporating, sputtering, or their combinations. Once the desired thickness is achieved, a metal patterning process is executed to form the bottom routing traces 157 electrically coupled to the second ends 107 of the metallized vias 156. As shown in FIG. 27, the bottom routing traces 157 include a patterned array of bond pads 154 that match chip I/O pads. Similarly, for a silicon substrate, an insulative/passivation layer (not shown in the figures) is needed on the substrate surface before routing trace formation.

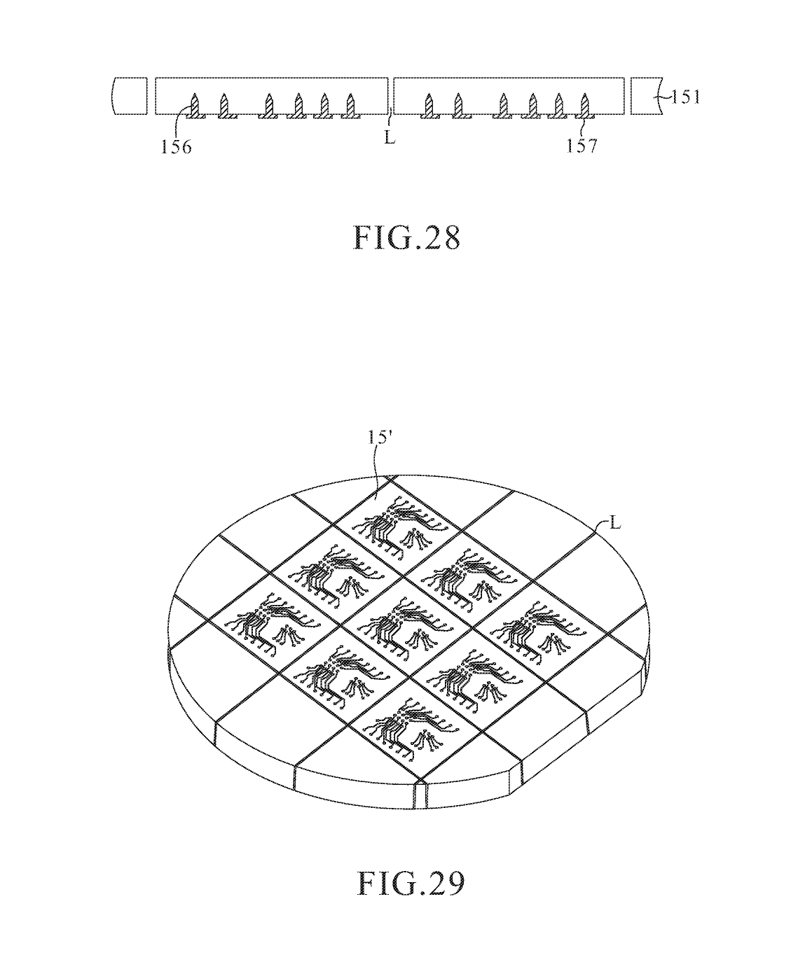

FIGS. 28 and 29 are cross-sectional and bottom perspective views, respectively, of the panel-scale structure of FIGS. 26 and 27 diced into individual pieces. The structure of FIGS. 26 and 27 is singulated into individual semi-finished interposer 15′ along dicing lines “L”.

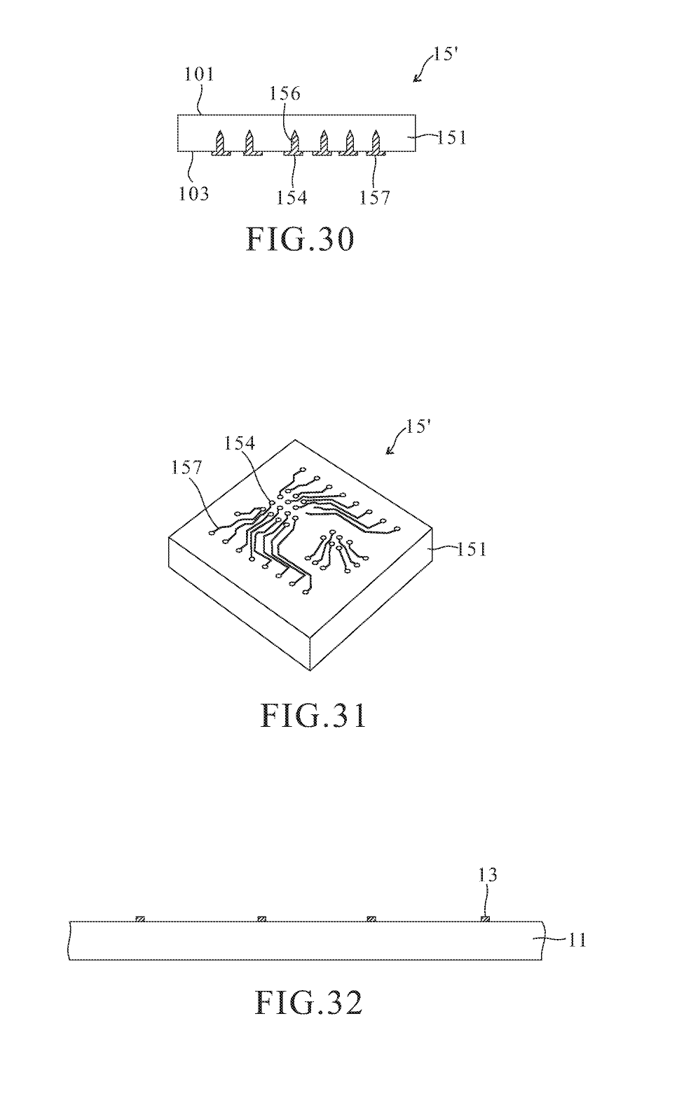

FIGS. 30 and 31 are cross-sectional and bottom perspective views, respectively, of an individual semi-finished interposer 15′ that includes a substrate 151, bond pads 154 and metallized vias 156. The metallized vias 156 are formed in the substrate 151 and electrically coupled to the bond pads 154 at the second surface 103 of the substrate 151.

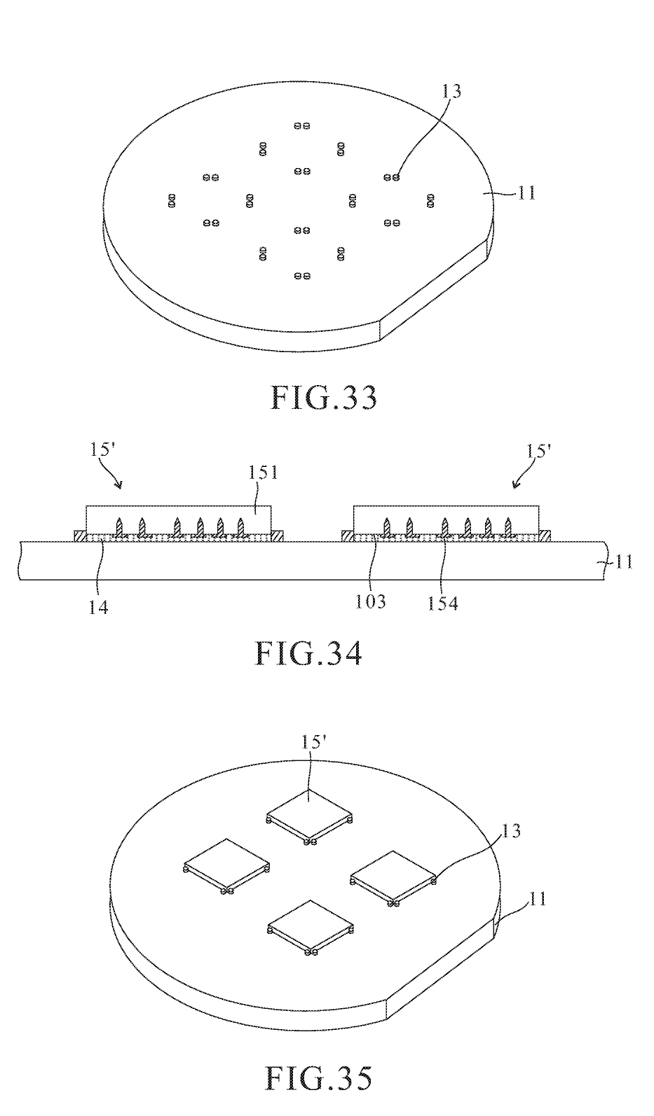

FIGS. 32 and 33 are cross-sectional and top perspective views, respectively, of the structure with multiple sets of alignment guides 13 on a sacrificial carrier 11. In this embodiment, each set of the alignment guides 13 consists of plural posts and conform to four corners of the subsequently disposed semi-finished interposer 15′.

FIGS. 34 and 35 are cross-sectional and top perspective views, respectively, of the structure with the semi-finished interposers 15′ of FIG. 30 attached to the sacrificial carrier 11 using an adhesive 14. The semi-finished interposers 15′ can be placed at predetermined locations by the alignment guides 13 laterally aligned with and in close proximity to the peripheral edges of the semi-finished interposers 15′ and the second surface 103 of the substrate 151 facing the sacrificial carrier 11 and in contact with the adhesive 14. As the alignment guides 13 extend from the sacrificial carrier 11 and extend beyond the second surface 103 of the substrate 151 in the upward direction, the alignment guides 13 can confine the dislocation of the semi-finished interposers 15′ laterally.

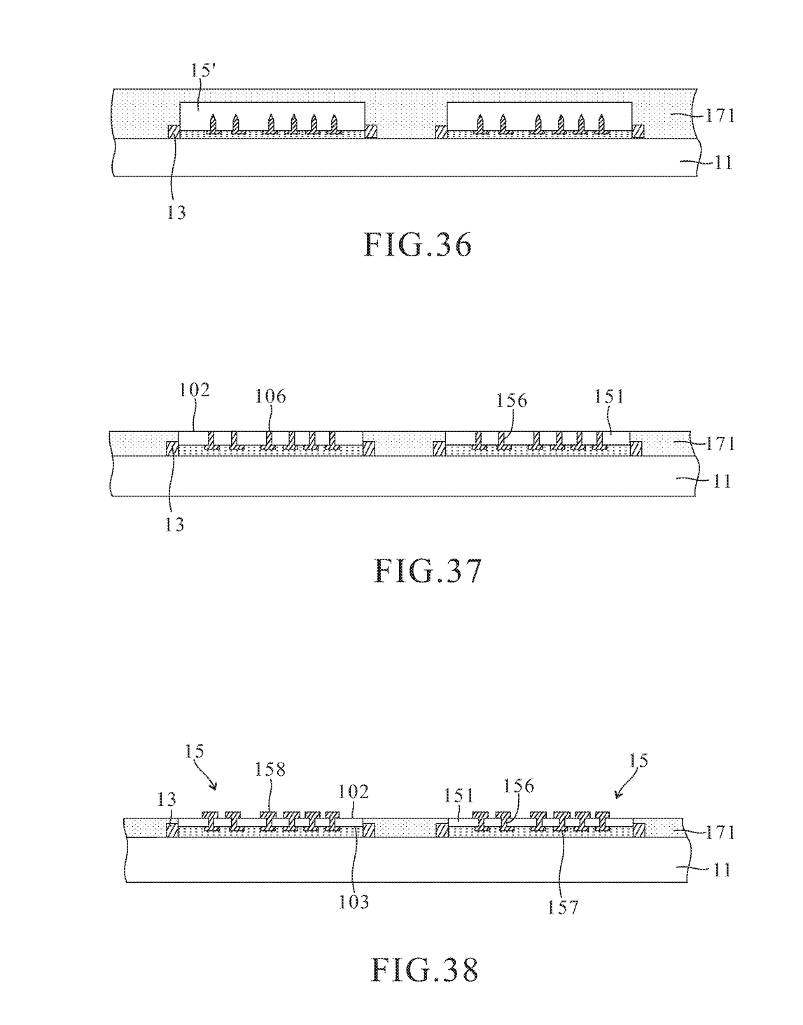

FIG. 36 is a cross-sectional view of the structure with a balancing layer 171 on the semi-finished interposers 15′ and the sacrificial carrier 11. The balancing layer 171 contacts and covers the sacrificial carrier 11, the alignment guides 13 and the semi-finished interposers 15′ from above, and surrounds and conformally coats sidewalls of the semi-finished interposers 15′.

FIG. 37 is a cross-sectional view of the structure with the first ends 106 of the metallized vias 156 exposed from above. Top portions of the balancing layer 171 and the substrate 151 are removed typically by lapping, grinding or laser to expose the first ends 106 of the metallized vias 156 from an exposed first surface 102 of the substrate 151. The exposed first surface 102 of the substrate 151 is substantially coplanar with the first ends 106 of the metallized vias 156 and the top surface of the balancing layer 171.

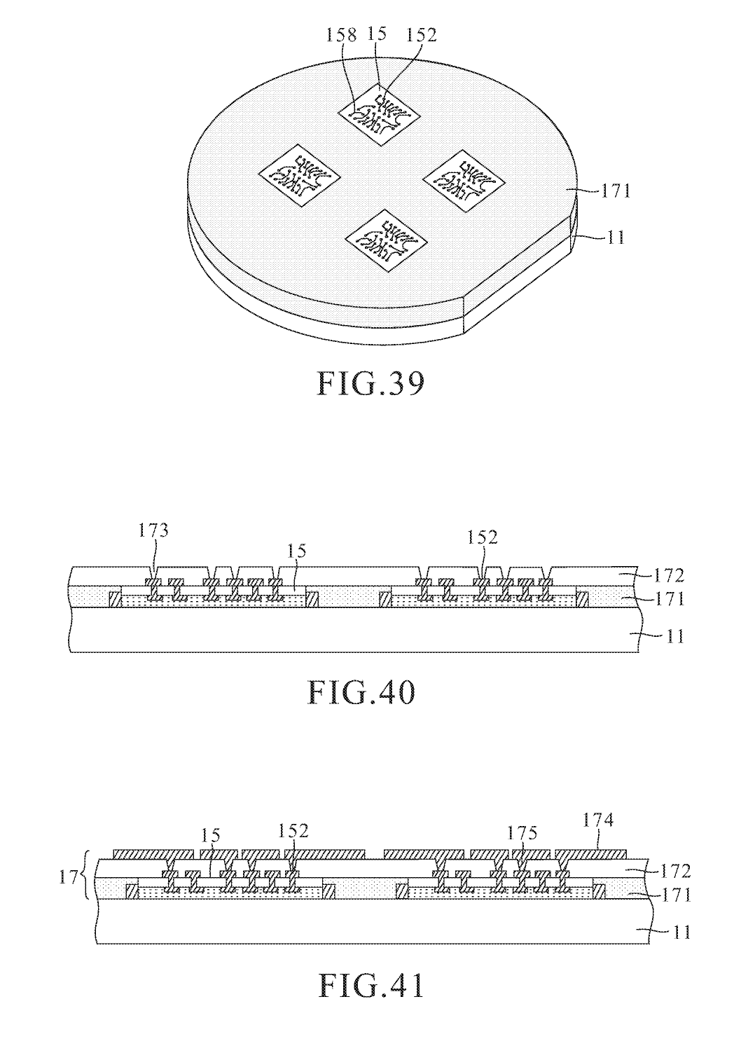

FIGS. 38 and 39 are cross-sectional and top perspective views, respectively, of the structure provided with top routing traces 158 by metal deposition and metal patterning process. The top routing traces 158 extend laterally on the first surface 102 of the substrate 151 and are electrically coupled to the first ends 106 of the metallized vias 156. As shown in FIG. 39, the top routing traces 158 include a patterned array of contact pads 152 that have a pitch larger than that of the bond pads 154.

At this stage, the fabrication of interposers 15 is finished, and each finished interposer 15 includes contact pads 152 at its first surface 102, bond pads 154 at its opposite second surface 103, and metallized vias 156 electrically coupled to the contact pads 152 and the bond pads 154. Accordingly, the finished interposers 15 can provide a primary fan-out routing to ensure a higher manufacturing yield for the next level buildup circuitry interconnection.

FIG. 40 is a cross-sectional view of the structure with a first dielectric layer 172 laminated/coated on the interposers 15 and the balancing layer 171 and first via openings 173 in the first dielectric layer 172. The first dielectric layer 172 contacts and covers and extends laterally on the interposer 15 and the balancing layer 171 from above. The first via openings 173 extend through the first dielectric layer 172 and are aligned with the contact pads 152 of the interposers 15.

Referring now to FIG. 41, first conductive traces 174 are formed on the first dielectric layer 172 by metal deposition and metal patterning process. The first conductive traces 174 extend from the contact pads 152 of the interposers 15 in the upward direction, fill up the first via openings 173 to form first conductive vias 175 in direct contact with the contact pads 152, and extend laterally on the first dielectric layer 172.

At this stage, the formation of a first wiring structure 17 on the interposers 15 is accomplished. In this illustration, the first wiring structure 17 includes a balancing layer 171, a first dielectric layer 172 and first conductive traces 174.

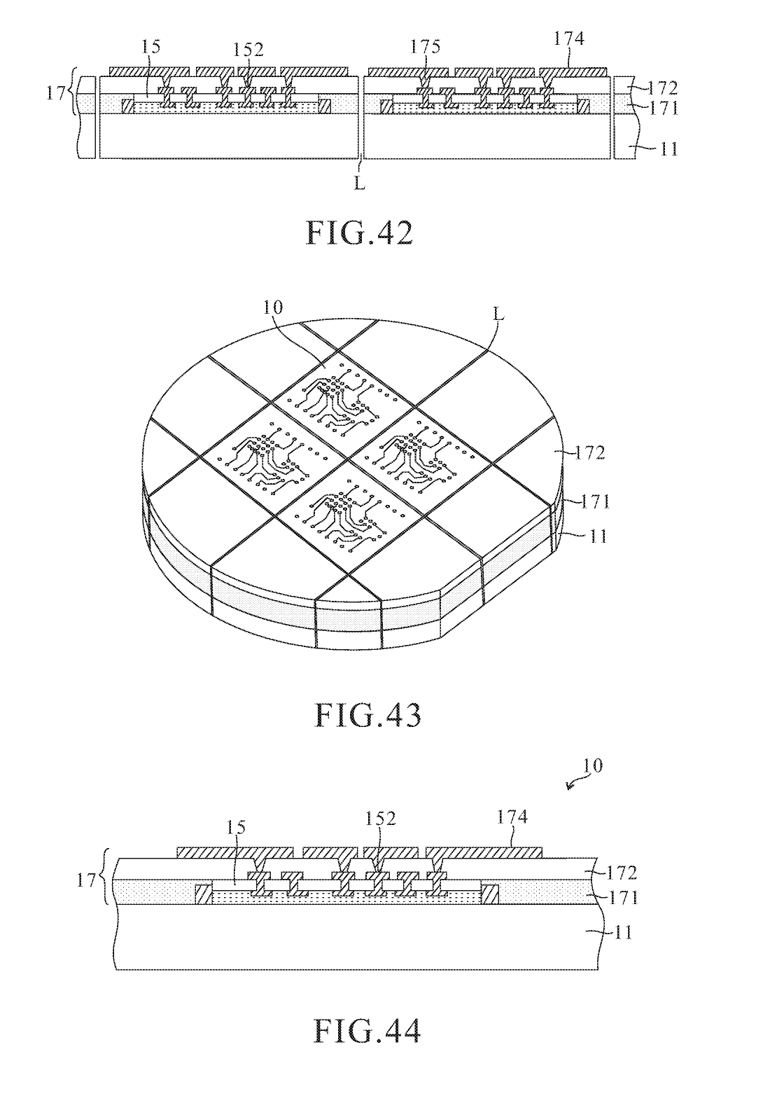

FIGS. 42 and 43 are cross-sectional and top perspective views, respectively, of the panel-scale structure of FIG. 41 diced into individual pieces. The panel-scale structure, having the first wiring structure 17 electrically coupled to the interposers 15, is singulated into individual electronic component 10 along dicing lines “L”.

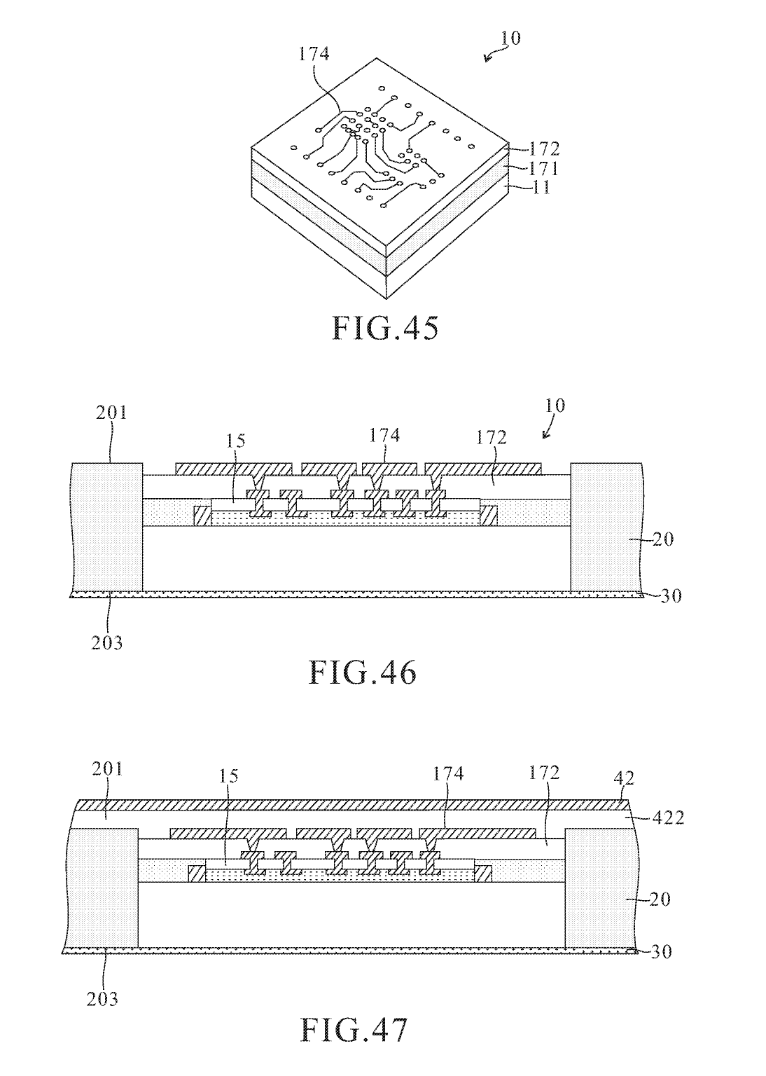

FIGS. 44 and 45 are cross-sectional and top perspective views, respectively, of an individual electronic component 10 that includes a sacrificial carrier 11, an alignment guide 13, an interposer 15 and a first wiring structure 17. In this illustration, the first wiring structure 17 is a buildup circuitry, and provide first level fan-out routing for the interposer 15.

FIG. 46 is a cross-sectional view of the structure with the electronic component 10 of FIG. 44 attached to the carrier film 30 of FIG. 14. The electronic component 10 is inserted into and steadily received within the through opening 205 of the stiffener 20 with the sacrificial carrier 11 attached on the carrier film 30. In this illustration, the outmost surface of the first wiring structure 17 is substantially coplanar with the first surface 201 of the stiffener 20 in the upward direction.

FIG. 47 is a cross-sectional view of the structure with a second dielectric layer 422 and a metal layer 42 laminated/coated on the electronic component 10 and the stiffener 20 from above. The second dielectric layer 422 contacts and is sandwiched between the first dielectric layer 172/the first conductive traces 174 and the metal layer 42 and between the stiffener 20 and the metal layer 42.

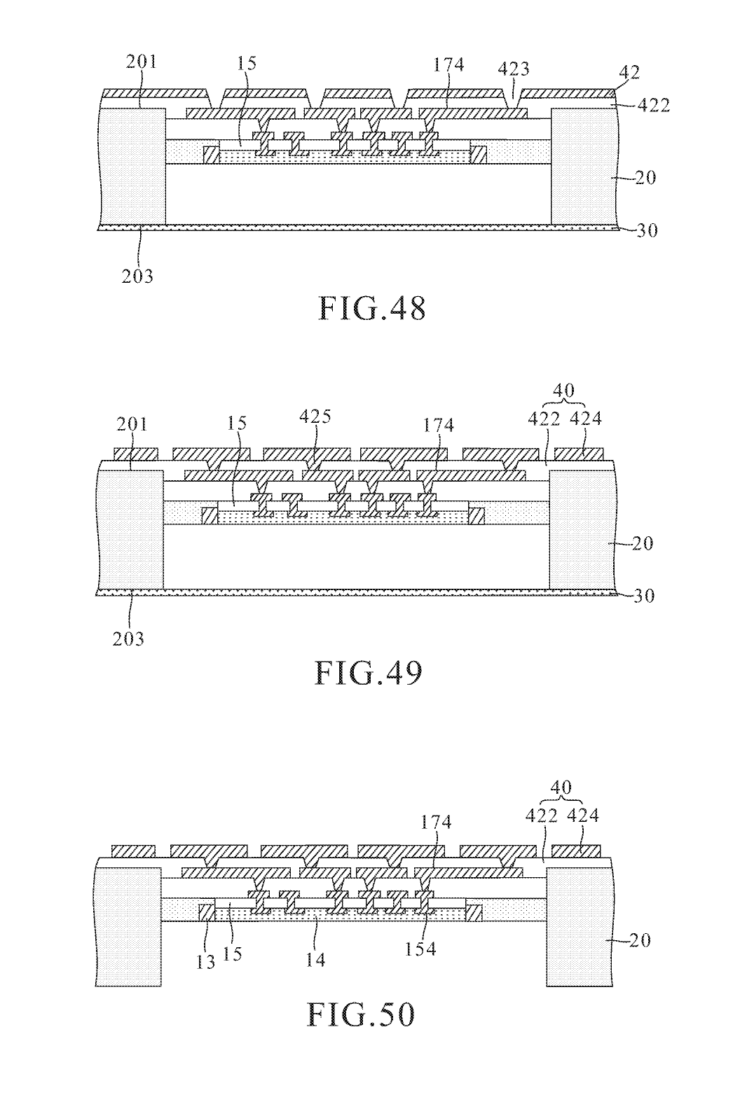

FIG. 48 is a cross-sectional view of the structure provided with the second via openings 423 to expose selected portions of the first conductive traces 174. The second via openings 423 extend through the metal layer 42 and the second dielectric layer 422, and are aligned with the selected portions of the first conductive traces 174.

Referring now to FIG. 49, second conductive traces 424 are formed on the second dielectric layer 422 by metal deposition and metal patterning process. The second conductive traces 424 extend from the first conductive traces 174 in the upward direction, fill up the second via openings 423 to form second conductive vias 425 in direct contact with the first conductive traces 174, and extend laterally on the second dielectric layer 422.

At this stage, the formation of a second wiring structure 40 on the first dielectric layer 172/the first conductive traces 174 of the electronic component 10 and the first surface 201 of the stiffener 20 is accomplished. In this illustration, the second wiring structure 40 includes a second dielectric layer 422 and second conductive traces 424.

FIG. 50 is a cross-sectional view of the structure after removal of the carrier film 30 and the sacrificial carrier 11. The carrier film 30 is detached from the sacrificial carrier 11 and the stiffener 20, followed by removing the sacrificial carrier 11.

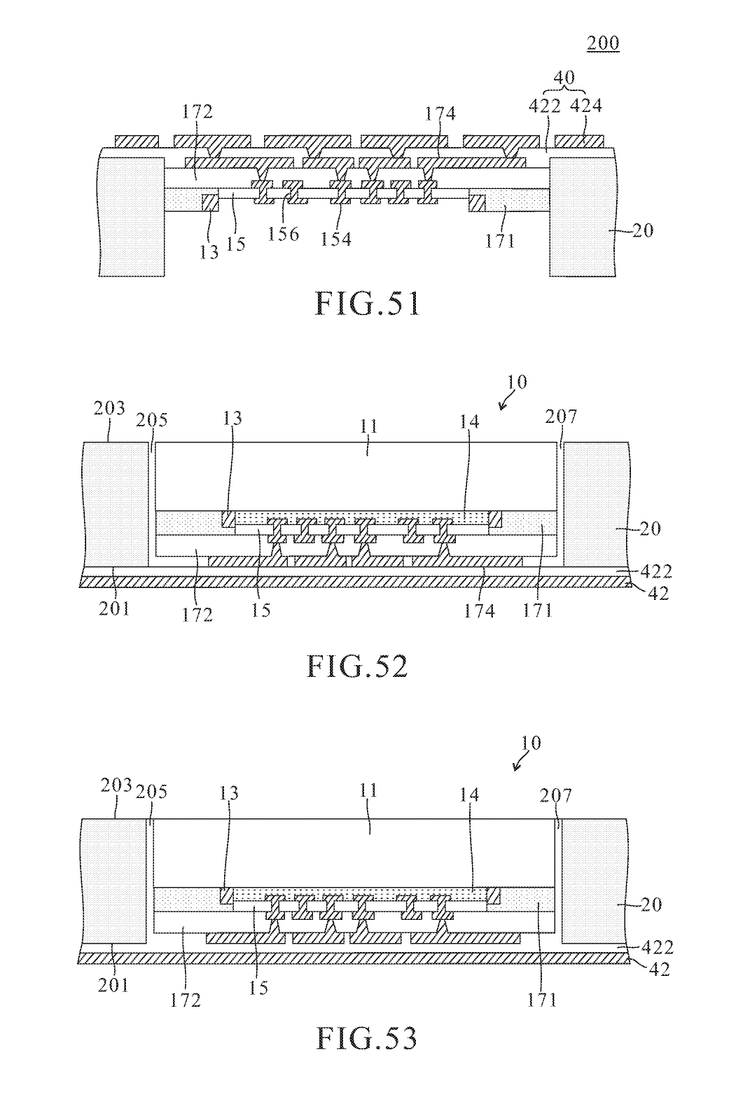

FIG. 51 is a cross-sectional view of the structure after removal of the adhesive 14. The adhesive 14 is removed from the second surface 103 of the interposer 15 so as to expose the bond pads 154 at the second surface 103 of the interposer 15 from below.

Accordingly, as shown in FIG. 51, a wiring board 200 is accomplished and includes an alignment guide 13, an interposer 15, a first wiring structure 17, a stiffener 20 and a second wiring structure 40, and both first and second wiring structures 17, 40 are sequentially formed buildup circuitries.

The interposer 15 and the first wiring structure 17 are positioned within the through opening 205 of the stiffener 20, whereas the second wiring structure 40 is disposed beyond the through opening 205 of the stiffener 20 and extends to peripheral edges of the wiring board 200. The interposer 15 contains a pattern of traces that fan out from a finer pitch at the bond pads 154 to a coarser pitch at the contact pads 152. As a result, a chip can be assembled on the bond pads 154 that match chip I/O pads, and buildup circuitry interconnection to the contact pads 152 can be executed in a higher manufacturing yield. The first wiring structure 17 covers the first surface 151 and sidewalls of the interposer 15 and has peripheral edges confined within the through opening 205 of the stiffener 20 and is electrically coupled to the contact pads 152 of the interposer 15 to provide fan-out routing for the interposer 15. The second wiring structure 40 contacts and laterally extends on the first wiring structure 17 and the stiffener 20, and is electrically coupled to the first wiring structure 17 to provide further fan-out routing.

### Embodiment 3

FIGS. 52-56 are schematic views showing yet another method of making a wiring board in which no carrier film is used and the second wiring structure is further electrically coupled to the stiffener for ground connection in accordance with yet another embodiment of the present invention.

For purposes of brevity, any description in Embodiments above is incorporated herein insofar as the same is applicable, and the same description need not be repeated.

FIG. 52 is a cross-sectional view of the structure with the electronic component 10 of FIG. 44 and a metallic stiffener 20 on a second dielectric layer 422/a metal layer 42. In this illustration, the second dielectric layer 422 is sandwiched between the electronic component 10 and the metal layer 42 and between the stiffener 20 and the metal layer 42, and contacts the first conductive traces 174 of the electronic component 10 and the first surface 201 of the stiffener 20. The surface of the first conductive traces 174 is substantially coplanar with the first surface 201 of the stiffener 20 in the downward direction, and a gap 207 is located in the through opening 205 between the electronic component 10 and the stiffener 20. The gap 207 is laterally surrounded by the stiffener 20, and laterally surrounds the sacrificial carrier 11 and the first wiring structure 17.

FIG. 53 is a cross-sectional view of the structure with the second dielectric layer 422 forced into the gap 207. The second dielectric layer 422 is flowed into the gap 207 by applying heat and pressure. Under the heat and pressure, the second dielectric layer 422 becomes compliant enough to conform to virtually any shape. As a result, the second dielectric layer 422 sandwiched between the electronic component 10 and the metal layer 42 and between the stiffener 20 and the metal layer 42 is compressed, forced out of its original shape and flows into and upward in the gap 207 to conformally coat sidewalls of the through opening 205 and peripheral edges of the sacrificial carrier 11 and the first wiring structure 17. The second dielectric layer 422 as solidified provides secure robust mechanical bonds between the electronic component 10 and the stiffener 20, between the electronic component 10 and the metal layer 42 and between the stiffener 20 and the metal layer 42, and thus retains the electronic component 10 within the through opening 205 of the stiffener 20.

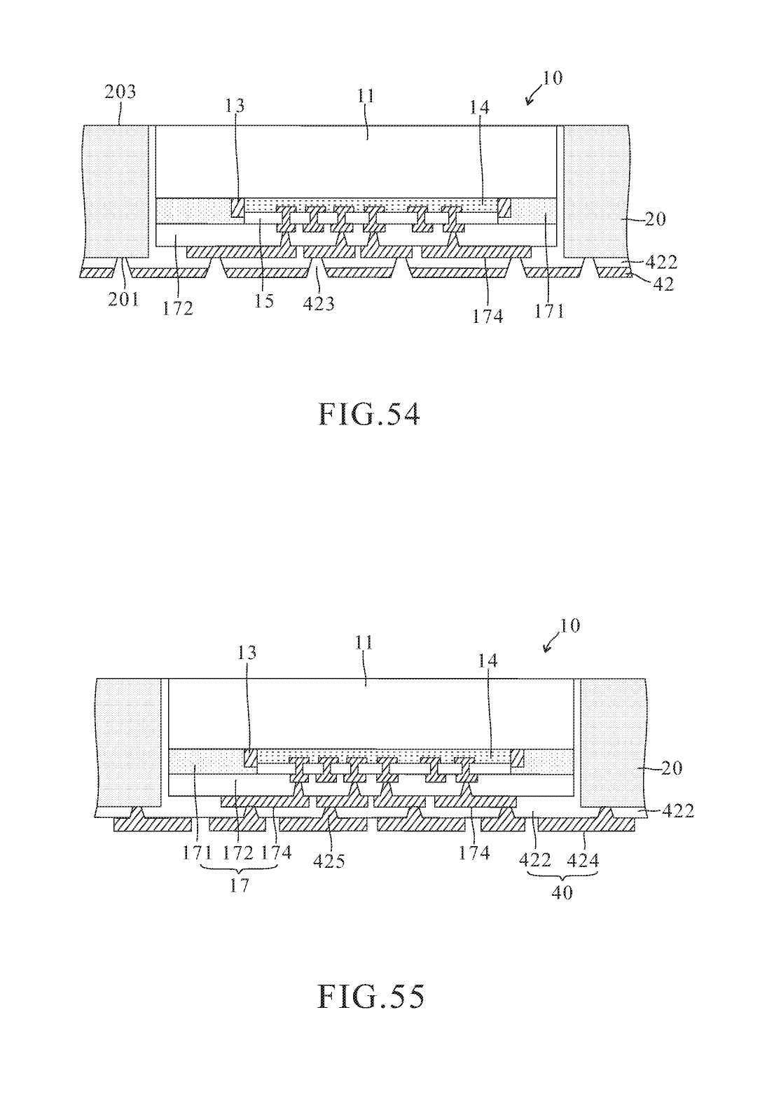

FIG. 54 is a cross-sectional view of the structure provided with the second via openings 423 to expose selected portions of the first conductive traces 174 and the stiffener 20. The second via openings 423 extend through the metal layer 42 and the second dielectric layer 422, and are aligned with selected portions of the first conductive traces 174 and the stiffener 20.

FIG. 55 is a cross-sectional view of the structure provided with second conductive traces 424 on the second dielectric layer 422 by metal deposition and metal patterning process. The second conductive traces 424 extend from the first conductive traces 174 and the stiffener 20 in the downward direction, fill up the second via openings 423 to form second conductive vias 425 in direct contact with the first conductive traces 174 and the stiffener 20, and extend laterally on the second dielectric layer 422.

At this stage, the formation of a second wiring structure 40 on the first wiring structure 17 and the stiffener 20 is accomplished. In this illustration, the second wiring structure 40 includes a second dielectric layer 422 and second conductive traces 424.

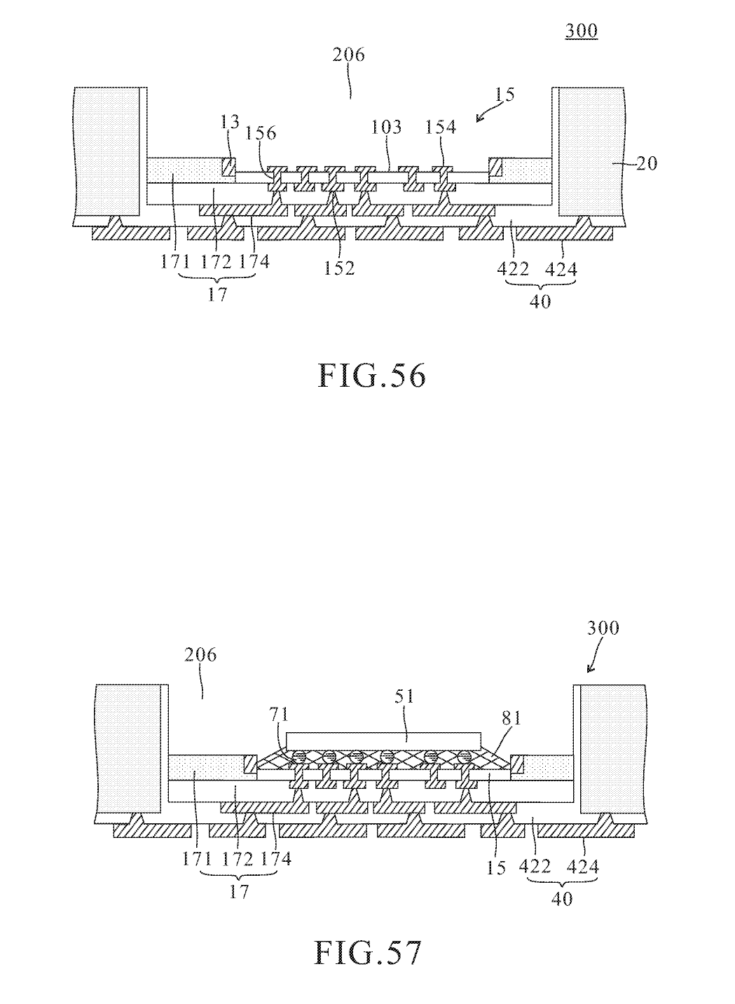

FIG. 56 is a cross-sectional view of the structure after removal of the sacrificial carrier 11 and the adhesive 14. As a result, the bond pads 154 at the second surface 103 of the interposer 15 are exposed from above and can serve as electrical contacts for chip connection.

Accordingly, as shown in FIG. 56, a wiring board 300 is accomplished and includes an alignment guide 13, an interposer 15, a first wiring structure 17, a stiffener 20 and a second wiring structure 40.

The interposer 15 is positioned within the through opening 205 of the stiffener 20, and includes bond pads 154 exposed from the through opening 205 of the stiffener 20 to provide electrical contacts from above for chip connection. The first wiring structure 17 is positioned within the through opening 205 of the stiffener 20 and encloses the interposer 15 and includes first conductive traces 174 electrically coupled to the contact pads 152 of the interposer 15 and laterally extending beyond peripheral edges of the interposer 15. The second wiring structure 40 is disposed beyond the through opening 205 of the stiffener 20 and includes second conductive traces 424 electrically coupled to the first conductive traces 174 of the first wiring structure 17 and the stiffener 20 and laterally extending beyond peripheral edges of the first wiring structure 17 and over the first surface 201 of the stiffener 20. The stiffener 20 extends beyond the top surfaces of the interposer 15 and the first wiring structure 17 in the upward direction to form a cavity 206 in the through opening 205 of the stiffener 20.

FIG. 57 is a cross-sectional view of a semiconductor assembly with a semiconductor device 51, illustrated as a chip, mounted on the wiring board 300 illustrated in FIG. 56. The semiconductor device 51 is positioned within the cavity 206 and is flip-chip mounted on the exposed bond pads 154 of the interposer 15 via solder bumps 71. Optionally, underfill 81 can be further provided to fill the gap between the semiconductor device 51 and the interposer 15.

The wiring boards and assemblies described above are merely exemplary. Numerous other embodiments are contemplated. In addition, the embodiments described above can be mixed-and-matched with one another and with other embodiments depending on design and reliability considerations. For instance, the stiffener may include multiple through openings arranged in an array and each through opening accommodates an interposer and a first wiring structure therein. Also, the second wiring structure can include additional conductive traces to receive and route additional first wiring structures, and additional alignment guides may be further provided and aligned with additional interposers.

As illustrated in the aforementioned embodiments, a distinctive wiring board is configured to exhibit improved reliability, which includes an interposer, a stiffener, a first wiring structure, a second wiring structure, and an optional alignment guide. For the convenience of following description, the direction in which the first surface of the interposer faces is defined as the first direction, and the direction in which the second surface of the interposer faces is defined as the second direction.

The interposer and the first wiring structure can be positioned within a through opening of the stiffener by inserting an electronic component, which includes the interposer and the first wiring structure on a detachable sacrificial carrier, into the through opening of the stiffener. In a preferred embodiment, the electronic component is inserted into the through opening of the stiffener, with peripheral edges of the first wiring structure and the sacrificial carrier in close proximity to sidewalls of the through opening of the stiffener. The interposer can be made of a silicon, glass or ceramic, and may be finished or semi-finished when it is attached to a detachable sacrificial carrier with its second surface facing the sacrificial carrier. By interposer backside process including grinding and circuitry formation, the semi-finished interposer can be fabricated into the finished-interposer that contain a pattern of traces that fan out from a finer pitch at its second surface to a coarser pitch at its first surface. Accordingly, the interposer can provide primary fan-out routing/interconnection for a semiconductor device to be assembled thereon. In a preferred embodiment, as the contact pads of the interposer have larger pad size than that of the bond pads thereof, micro-via connection failure in the subsequent formation of the buildup circuitry can be avoided. Additionally, as the interposer is typically made of a high elastic modulus material with CTE (coefficient of thermal expansion) approximately equal to that of the chip (for example, 3 to 10 ppm per degree Centigrade), internal stresses in chip and its electrical interconnection caused by CTE mismatch can be largely compensated or reduced.

The electronic component can be fabricated by steps of: attaching the interposer to the sacrificial carrier using the adhesive, with the second surface of the interposer facing the sacrificial carrier; forming a balancing layer that covers the sacrificial carrier and the sidewalls of the interposer; and forming at least one wiring layer on the interposer and the balancing layer to finish the step of forming the first wiring structure that includes the balancing layer and the wiring layer, wherein the wiring layer is electrically coupled to the contact pads of the interposer. Alternatively, the electronic component may be fabricated by steps of: providing a semi-finished interposer that includes a substrate having a first surface and an opposite second surface, bond pads at the second surface of the substrate, and metallized vias, each of which is formed in the substrate and has a first end spaced from the first surface of the substrate and an opposite second end electrically coupled to the bond pads; attaching the semi-finished interposer on the sacrificial carrier using an adhesive with the second surface of the substrate facing the sacrificial carrier; providing a balancing layer that covers the sacrificial carrier and semi-finished interposer; removing portions of the balancing layer and the semi-finished interposer to expose the first ends of the metallized vias with the substrate having an exposed first surface substantially coplanar with the first ends of the metallized vias; forming contact pads at the exposed first surface of the substrate to finish fabrication of an interposer that includes the contact pads and the bond pads respectively on opposite first and second surfaces thereof and the metallized vias electrically coupled to the bond pads and the contact pads; and forming at least one wiring layer on the interposer and the balancing layer to finish the step of forming the first wiring structure that includes the balancing layer and the wiring layer, wherein the wiring layer is electrically coupled to the contact pads of the interposer. Preferably, the electronic component is fabricated by a panel scale process followed by a singulation process. Further, the electronic component can further include an alignment guide projecting from a surface of the sacrificial carrier. In a preferred embodiment, the alignment guide extends from a surface of the sacrificial carrier and extends beyond the second surface of the finished or semi-finished interposer in the first direction. As such, the placement accuracy of the finished or semi-finished interposer can be provided by the alignment guide that is laterally aligned with and in close proximity to the peripheral edges of the finished or semi-finished interposer. The alignment guide can have various patterns against undesirable movement of the finished or semi-finished interposer. For instance, the alignment guide can include a continuous or discontinuous strip or an array of posts. Alternatively, the alignment guide may laterally extend to the peripheral edges of the sacrificial carrier and have inner peripheral edges that conform to the peripheral edges of the finished or semi-finished interposer. Specifically, the alignment guide can be laterally aligned with four lateral surfaces of the finished or semi-finished interposer to define an area with the same or similar topography as the finished or semi-finished interposer and prevent the lateral displacement of the finished or semi-finished interposer. For instance, the alignment guide can be aligned along and conform to four sides, two diagonal corners or four corners of the finished or semi-finished interposer so as to confine the dislocation of the finished or semi-finished interposer laterally. Besides, the alignment guide around the second surface of the finished or semi-finished interposer preferably has a height in a range of 5-200 microns, and may be simultaneously removed while removing the sacrificial carrier.

The stiffener may be a single or multi-layer structure optionally with embedded single-level conductive traces or multi-level conductive traces. In a preferred embodiment, the stiffener surrounds peripheral edges of the first wiring structure and laterally extends to the peripheral edges of the wiring board. The stiffener can be made of any material which has enough mechanical robustness, such as metal, composites of metal, ceramic, resin or other non-metallic materials. Accordingly, the stiffener located around peripheral edges of the first wiring structure can provide mechanical support for the wiring board to suppress warping and bending of the wiring board.

The first and second wiring structures can be sequentially formed buildup circuitries without a core layer and positioned within and disposed beyond the through opening of the stiffener, respectively. The first wiring structure laterally extends beyond the peripheral edges of the interposer, and has peripheral edges confined within the through opening of the stiffener. The second wiring structure laterally extends beyond the peripheral edges of the first wiring structure, and can further laterally extend to peripheral edges of the wiring board to substantially have a combined surface area of the first wiring structure and the stiffener. As such, in a preferred embodiment, the first wiring structure has a larger surface area than that of the interposer, whereas the second wiring structure has a larger surface area than that of the first wiring structure. The first and second wiring structures each can include at least one dielectric layer and conductive traces that fill up via openings in the dielectric layer and extend laterally on the dielectric layer. The dielectric layer and the conductive traces are serially formed in an alternate fashion and can be in repetition when needed.

The first wiring structure covers the first surface and sidewalls of the interposer and is electrically coupled to the contact pads of the interposer so as to provide fan-out routing/interconnection for the interposer. Specifically, the first wiring structure can include a balancing layer laterally surrounding the interposer, a dielectric layer on the interposer and the balancing layer, and conductive traces that extend from the contact pads of the interposer and fill up via openings in the dielectric layer to form conductive vias and laterally extend on the dielectric layer. As such, the first wiring structure can be electrically coupled to the contact pads of the interposer through conductive vias in direct contact with the contact pads of the interposer. The first wiring structure preferably has a first surface facing the first direction and substantially coplanar with the first surface of the stiffener and in contact with the second wiring structure, and an opposite second surface facing the second direction and exposed from the through opening of the stiffener after removing the sacrificial carrier. Further, the stiffener can extend beyond the second surface of the first wiring structure in the second direction so as to form a cavity in the through opening of the stiffener. Accordingly, a semiconductor device can be positioned within the cavity and electrically coupled to the bond pads of the interposer exposed from the cavity. Optionally, an adhesive may be dispensed in a gap located in the through opening between the electronic component and the stiffener after the electronic component is inserted into the through opening of the stiffener, thereby providing secure robust mechanical bonds between the first wiring structure and the stiffener. Alternatively, the gap between the electronic component and the stiffener may be filled with a dielectric layer of the second wiring structure. Accordingly, the sidewalls of the through opening and the peripheral edges of the first wiring structure and the sacrificial carrier can be coated with the adhesive or the dielectric layer.

The second wiring structure can be formed on the first surfaces of the first wiring structure and the stiffener to provide further fan-out routing/interconnection after the insertion of the electronic component into the through opening of the stiffener. As the second wiring structure can be electrically coupled to the first wiring structure through conductive vias of the second wiring structure, the electrical connection between the first wiring structure and the second wiring structure can be devoid of soldering material. Also, the interface between the stiffener and the second wiring structure can be devoid of solder or adhesive. More specifically, the second wiring structure can be formed to include a dielectric layer on the first surfaces of the first wiring structure and the stiffener, and conductive traces that extend from the outmost conductive traces of the first wiring structure and optionally from the first surface of the stiffener and fill up via openings in the dielectric layer of the second wiring structure and laterally extend on the dielectric layer of the second wiring structure. As a result, the second wiring structure can contact and be electrically coupled to the outmost conductive traces of the first wiring structure for signal routing, and optionally further electrically coupled to the first surface of the stiffener for ground connection. The outmost conductive traces of the second wiring structure can accommodate conductive joints, such as solder balls, for electrical communication and mechanical attachment with for the next level assembly or another electronic device.

Before the formation of the second wiring structure, a carrier film (typically an adhesive tape) may be used to provide temporary retention force. For instance, the carrier film can temporally adhere to the sacrificial carrier and the second surface of the stiffener to retain the electronic component within the through opening of the stiffener, optionally followed by dispensing an adhesive in a gap between the stiffener and the first wiring structure and between the stiffener and the sacrificial carrier, as mentioned above. After the second wiring structure is formed on the first wiring structure and the stiffener, the carrier film can be detached therefrom. As an alternative, the electronic component and the stiffener may be directly positioned on a dielectric layer, with the outmost conductive traces of the first wiring structure and the first surface of the stiffener in contact with the dielectric layer, followed by bonding the dielectric layer to the first wiring structure and the stiffener, preferably with the dielectric layer flowed into the gap between the first wiring structure and the stiffener and between the sacrificial carrier and the stiffener. As a result, the dielectric layer can provide secure robust mechanical bonds between the electronic component and the stiffener and retain the electronic component within the through opening of the stiffener. Subsequently, the second wiring structure, including the dielectric layer bonded to the first wiring structure and the stiffener, can be formed to electrically couple the first wiring structure.

The sacrificial carrier, which provides rigidity support for the interposer and the first wiring structure, can be detached from the interposer and the first wiring structure by a chemical etching process or a mechanical peeling process after the formation of the second wiring structure. The sacrificial carrier can have a thickness of 0.1 mm to 2.0 mm and may be made of any conductive or non-conductive material.

The present invention also provides a semiconductor assembly in which a semiconductor device is electrically coupled to the bond pads of the aforementioned wiring board. Specifically, the semiconductor device can be positioned in the cavity of the wiring board and electrically connected to the wiring board using various using a wide variety of connection media such as bumps on the bond pads of the wiring board. The semiconductor device can be a packaged or unpackaged chip. For instance, the semiconductor device can be a bare chip, or a wafer level packaged die, etc. Alternatively, the semiconductor device can be a stacked-die chip. Optionally, a filler material can be further provided to fill the gap between the semiconductor device and the interposer of the wiring board.

The term “cover” refers to incomplete or complete coverage in a vertical and/or lateral direction. For instance, in the cavity-up position, the second wiring structure covers the interposer in the downward direction regardless of whether another element such as the first wiring structure is between the interposer and the second wiring structure.

The phrases “mounted on” and “attached on” include contact and non-contact with a single or multiple element(s). For instance, the interposer is attached on the sacrificial carrier regardless of whether it is separated from the sacrificial carrier by an adhesive.

The phrase “aligned with” refers to relative position between elements regardless of whether elements are spaced from or adjacent to one another or one element is inserted into and extends into the other element. For instance, the alignment guide is laterally aligned with the interposer since an imaginary horizontal line intersects the alignment guide and the interposer, regardless of whether another element is between the alignment guide and the interposer and is intersected by the line, and regardless of whether another imaginary horizontal line intersects the interposer but not the alignment guide or intersects the alignment guide but not the interposer. Likewise, the electronic component is aligned with the through opening of the stiffener.

The phrase “in close proximity to” refers to a gap between elements not being wider than the maximum acceptable limit. As known in the art, when the gap between the interposer and the alignment guide is not narrow enough, the location error of the interposer due to the lateral displacement of the interposer within the gap may exceed the maximum acceptable error limit. In some cases, once the location error of the interposer goes beyond the maximum limit, it is impossible to align the predetermined portion of the interposer with a laser beam, resulting in the electrical connection failure between the interposer and the buildup circuitry. According to the contact pad size of the interposer, those skilled in the art can ascertain the maximum acceptable limit for a gap between the interposer and the alignment guide through trial and error to ensure the conductive vias being aligned with the contact pads of the interposer. Thereby, the description “the alignment guide is in close proximity to the peripheral edges of the interposer (or the semi-finished interposer)” means that the gap between the peripheral edges of the interposer (or the semi-finished interposer) and the alignment guide is narrow enough to prevent the location error of the interposer (or the semi-finished interposer) from exceeding the maximum acceptable error limit. Likewise, the description “peripheral edges of the first wiring structure and the sacrificial carrier are in close proximity to sidewalls of the through opening of the stiffener” means that the gap between the peripheral edges of the sacrificial carrier and the sidewalls of the through opening and between the peripheral edges of the first wiring structure and the sidewalls of the through opening is narrow enough to prevent the location error of the electronic component from exceeding the maximum acceptable error limit. For instance, the gaps in between the interposer (or the semi-finished interposer) and the alignment guide may be in a range of about 5 to 50 microns, and the gaps in between the peripheral edges of the electronic component and the sidewalls of the through opening preferably may be in a range of about 10 to 50 microns.

The phrases “electrical connection”, “electrically connected” and “electrically coupled” refer to direct and indirect electrical connection. For instance, the conductive traces of the first wiring structure directly contact and are electrically connected to the contact pads of the interposer and the conductive traces of the second wiring structure are spaced from and electrically connected to the contact pads of the interposer by the first wiring structure.

The “first direction” and “second direction” do not depend on the orientation of the wiring board, as will be readily apparent to those skilled in the art. For instance, the first surfaces of the interposer, the first wiring structure and the stiffener face the first direction and the second surfaces of the interposer, the first wiring structure and the stiffener face the second direction regardless of whether the wiring board is inverted. Thus, the first and second directions are opposite one another and orthogonal to the lateral directions. Furthermore, the first direction is the downward direction and the second direction is the upward direction in the cavity-up position, and the first direction is the upward direction and the second direction is the downward direction in the cavity-down position.

The wiring board according to the present invention has numerous advantages. For instance, the stiffener can provide an anti-warping platform for the second wiring structure formation thereon to suppress warping and bending of the wiring board. The interposer provides a primary fan-out routing/interconnection and a CTE-matched interface for a semiconductor device to be assembled thereon. The integrated dual wiring structures provide a staged fan-out routing/interconnection for the interposer. As such, a semiconductor device with fine pads can be electrically coupled to one side of the interposer with pad pitch that matches the semiconductor device, and the integrated dual wiring structures are electrically coupled to the other side of the interposer with larger pad pitch and further enlarges the pad size and pitch of the semiconductor device. The alignment guide can provide critical placement accuracy for the interposer. By the mechanical robustness of the stiffener, the warping problem can be resolved. The wiring board made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A wiring board with integrated interposer and dual wiring structures, comprising:
an interposer having contact pads at a first surface thereof, bond pads at an opposite second surface thereof, and metallized vias electrically coupled to the bond pads and the contact pads;
a first wiring structure that covers the first surface and sidewalls of the interposer and is electrically coupled to the contact pads of the interposer and includes at least one conductive trace laterally extending beyond peripheral edges of the interposer;
a second wiring structure that is electrically coupled to the first wiring structure and includes at least one conductive trace laterally extending over and beyond peripheral edges of the first wiring structure; and
a stiffener having a through opening that extends through the stiffener, wherein the interposer and the first wiring structure are positioned within the through opening of the stiffener and the second wiring structure is disposed beyond the through opening of the stiffener and on an exterior surface of the stiffener.

2. The wiring board of claim 1, wherein the interposer has a smaller surface area than that of the first wiring structure, and the first wiring structure has a smaller surface area than that of the second wiring structure.

3. The wiring board of claim 1, wherein the interposer has a smaller thermal expansion coefficient and higher modulus than that of the first and second wiring structures.

4. A method of making a wiring board with integrated interposer and dual wiring structures, comprising:
providing an electronic component that includes a detachable sacrificial carrier, an interposer and a first wiring structure, wherein (i) the interposer has contact pads at a first surface thereof, bond pads at an opposite second surface thereof and metallized vias electrically coupled to the contact pads and the bond pads, and is disposed over the sacrificial carrier with the second surface facing the sacrificial carrier; and (ii) the first wiring structure covers the sacrificial carrier and the first surface and sidewalls of the interposer and is electrically coupled to the contact pads of the interposer and includes at least one conductive trace laterally extending beyond peripheral edges of the interposer;
providing a stiffener that has a through opening extending through the stiffener;
inserting the electronic component into the through opening of the stiffener;
forming a second wiring structure that is electrically coupled to the first wiring structure and disposed beyond the through opening of the stiffener and on an exterior surface of the stiffener and includes at least one conductive trace laterally extending over and beyond peripheral edges of the first wiring structure; and
removing the sacrificial carrier to expose the bond pads of the interposer.

5. The method of claim 4, wherein the electronic component is fabricated by steps of:
attaching the interposer to the sacrificial carrier using an adhesive, with the second surface facing the sacrificial carrier;
forming a balancing layer that covers the sacrificial carrier and the sidewalls of the interposer; and
forming at least one wiring layer on the interposer and the balancing layer to finish the step of forming the first wiring structure that includes the balancing layer and the wiring layer, wherein the wiring layer is electrically coupled to the contact pads of the interposer.

6. The method of claim 5, wherein the electronic component further includes an alignment guide projecting from a surface of the sacrificial carrier, and the interposer is attached to the sacrificial carrier, with the alignment guide laterally aligned with and in close proximity to peripheral edges of the interposer and extending beyond the second surface of the interposer.

7. The method of claim 4, wherein the electronic component is fabricated by steps of:
providing a semi-finished interposer that includes a substrate having a first surface and an opposite second surface, bond pads at the second surface of the substrate, and metallized vias, each of which is formed in the substrate and has a first end spaced from the first surface of the substrate and an opposite second end electrically coupled to the bond pads;
attaching the semi-finished interposer on the sacrificial carrier using an adhesive with the second surface of the substrate facing the sacrificial carrier;
providing a balancing layer that covers the sacrificial carrier and semi-finished interposer;
removing portions of the balancing layer and the semi-finished interposer to expose the first ends of the metallized vias with the substrate having an exposed first surface substantially coplanar with the first ends of the metallized vias;
forming contact pads at the exposed first surface of the substrate to finish fabrication of the interposer that includes the contact pads and the bond pads respectively on opposite first and second surfaces thereof and the metallized vias electrically coupled to the bond pads and the contact pads; and
forming at least one wiring layer on the interposer and the balancing layer to finish the step of forming the first wiring structure that includes the balancing layer and the wiring layer, wherein the wiring layer is electrically coupled to the contact pads of the interposer.

8. The method of claim 7, wherein the electronic component further includes an alignment guide projecting from a surface of the sacrificial carrier, and the semi-finished interposer is attached to the sacrificial carrier, with the alignment guide laterally aligned with and in close proximity to peripheral edges of the semi-finished interposer and extending beyond the second surface of the semi-finished interposer.
